(19) United States
(12) Patent Application Publication
(10) Pub. No.: US 2023/0154913 A1
(43) Pub. Date: May 18, 2023

(54) METHOD AND STRUCTURE FOR 3DIC POWER DISTRIBUTION

(71) Applicant: Taiwan Semiconductor Manufacturing Co., Ltd., Hsinchu (TW)

(72) Inventors: Chung-Hao Tsai, Huatan Township (TW); Tzu-Chun Tang, Kaohsiung (TW); Chuei-Tang Wang, Taichung (TW)

(21) Appl. No.: 17/703,700

(22) Filed: Mar. 24, 2022

Related U.S. Application Data
(60) Provisional application No. 63/278,525, filed on Nov. 12, 2021.

(51) Int. Cl. H01L 25/00; H01L 25/065; H01L 23/538; H01L 23/367; H01L 25/18; H01L 21/56

(52) U.S. Cl. CPC H01L 25/50; H01L 25/0657; H01L 23/5389; H01L 23/367; H01L 25/18; H01L 21/568; H01L 24/08

(57) ABSTRACT

Embodiments provide regulated power routing through various inactive features of a device. In one embodiment, such inactive features include a through via wall which can be formed in an encapsulating material of a die stack. In another embodiment, such inactive features include a heat dissipation features formed over the die stack. In another embodiment, such inactive features include dummy via blocks attached adjacent a die cube. Yet other embodiments may combine the features of these embodiments without limitation.

### PRIORITY CLAIM AND CROSS-REFERENCE

This application claims the benefit of U.S. Provisional Application No. 63,278,525, filed on Nov. 12, 2021, which application is hereby incorporated herein by reference.

### BACKGROUND

The packages of integrated circuits are becoming increasing complex, with more device dies packaged in the same package to achieve more functions. For example, System on Integrate Chip (SoIC) has been developed to include a plurality of device dies such as processors and memory cubes in the same package. The SoIC can include device dies formed using different technologies and have different functions bonded to the same device die, thus forming a system. This may save manufacturing cost and optimize device performance.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1 through 17 illustrate various views of intermediate stages of the formation of a package device, in accordance with some embodiments.

FIGS. 18 through 22 illustrate various views of intermediate stages of the formation of a package device, in accordance with other embodiments.

FIGS. 23 through 35A, 35B, 35C, and 35D illustrate various views of intermediate stages of the formation of a package device, in accordance with other embodiments.

FIGS. 36 through 46 illustrate various views of intermediate stages of the formation of a package device, in accordance with other embodiments.

FIGS. 47 through 48A, 48B, 48C, and 48D illustrate various views of a package device, in accordance with other embodiments.

FIG. 49 illustrates a package device, in accordance with some embodiments.

FIG. 50 illustrates a package device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments provide several configurations for power distribution in a 3DIC package. Power may be provided to package components (i.e., package devices) by a voltage regulator which may be located internally or externally to the 3DIC package. Embodiments utilize large conductive lines and/or conductive via walls to distribute power to each of the components of the 3DIC package. As a result, internal resistance is reduced, which helps reduce waste heat generation. Further, the conductive paths provide a conduit for heat dissipation for providing efficient heat dissipation for the heat that is generated from the power distribution and from the operation of the various components of the 3DIC package.

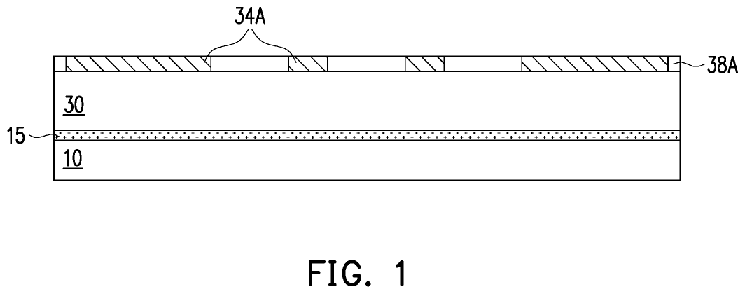

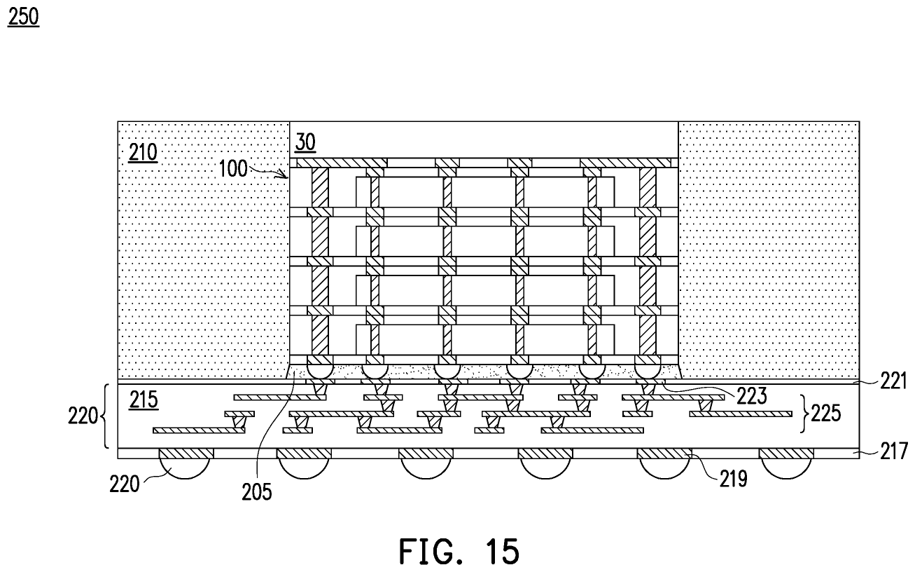

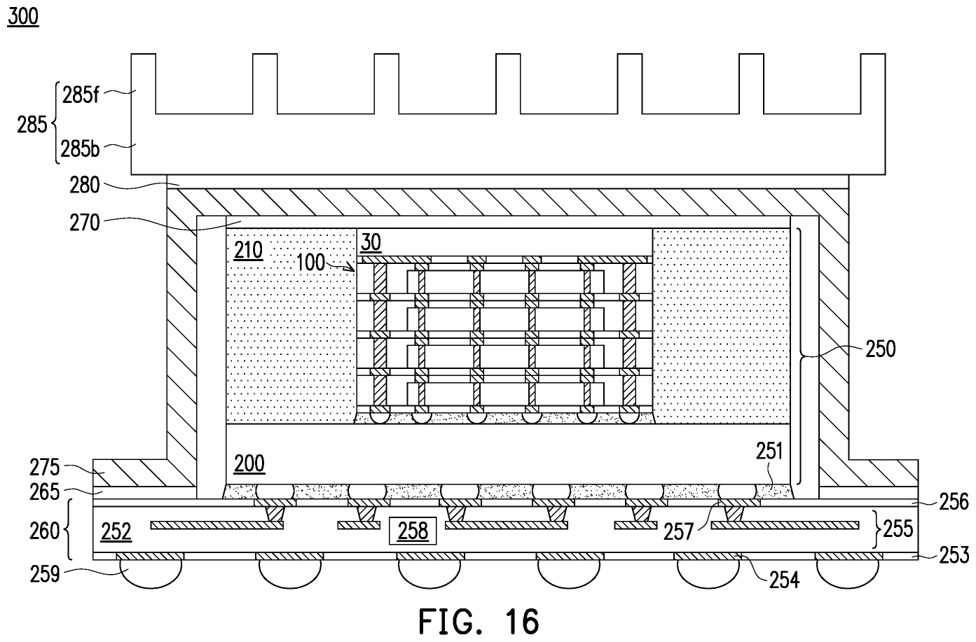

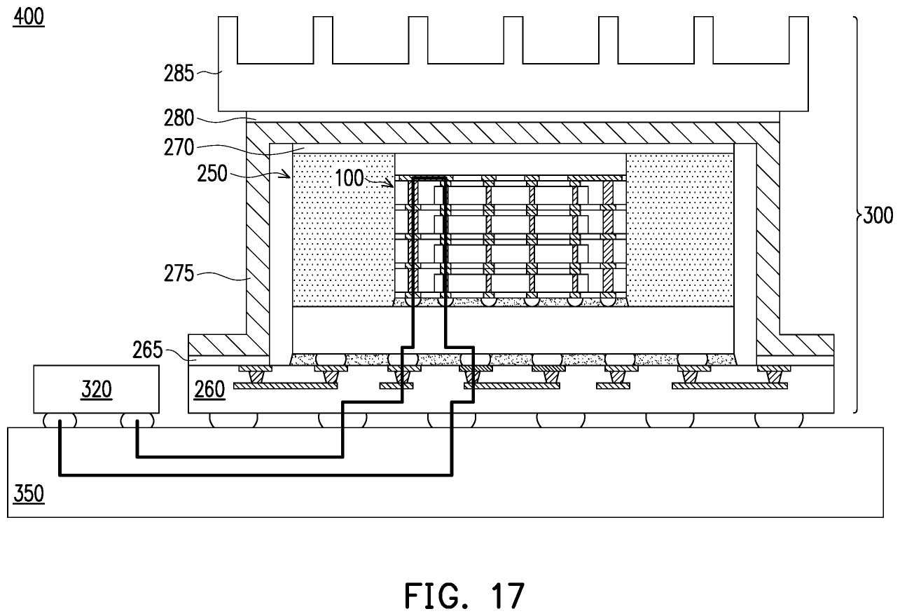

FIGS. 1 through 14 illustrate intermediate stages in the formation of a 3DIC package, in accordance with some embodiments. FIG. 15 illustrates using the 3DIC package of FIGS. 1 through 14 in a chip-on-wafer (CoW) package. FIG. 16 illustrates using the CoW package of FIG. 15 in a chip-on-wafer-on-substrate (CoWoS) package. FIG. 17 illustrates using the CoWoS package on a printed circuit board, and demonstrates the power routing advantages present in the CoWoS package.

In FIG. 1, a carrier substrate 10 is provided and a release layer 15 is formed on the carrier substrate 10. The carrier substrate 10 may be a glass carrier substrate, a ceramic carrier substrate, or the like. The carrier substrate 10 may be a wafer, such that multiple packages can be formed on the carrier substrate 10 simultaneously.

The release layer 15 may be formed of a polymer-based material, which may be removed along with the carrier substrate 10 from the overlying structures that will be formed in subsequent steps. In some embodiments, the release layer 15 is an epoxy-based thermal-release material, which loses its adhesive property when heated, such as a light-to-heat-conversion (LTHC) release coating. In other embodiments, the release layer 15 may be an ultra-violet (UV) glue, which loses its adhesive property when exposed to UV lights. The release layer 15 may be dispensed as a liquid and cured, may be a laminate film laminated onto the carrier substrate 10, or may be the like. The top surface of the release layer 15 may be leveled and may have a high degree of planarity.

The device die 30 is attached to the carrier substrate 10 via the release layer 15. In some embodiments, the device die 30 is a chip or die placed on and chip-on-wafer bonded to the carrier substrate 10 through a pick and place process. In other embodiments, the device die 30 is formed directly on the carrier substrate 10. In yet other embodiments, the device die 30 may be disposed within a wafer which is wafer-to-wafer bonded to the carrier substrate 10. The device die 30 as illustrated may be one of a plurality of such device dies 30 attached to the carrier substrate 10. The device die 30 may be a logic die, such as a Central Processing Unit (CPU) die, a Micro Control Unit (MCU) die, an input-output (IO) die, a BaseBand (BB) die, an Application processor (AP) die, or the like. The device die 30 may also be a memory die such as a Dynamic Random Access Memory (DRAM) die or a Static Random Access Memory (SRAM) die, or the like.

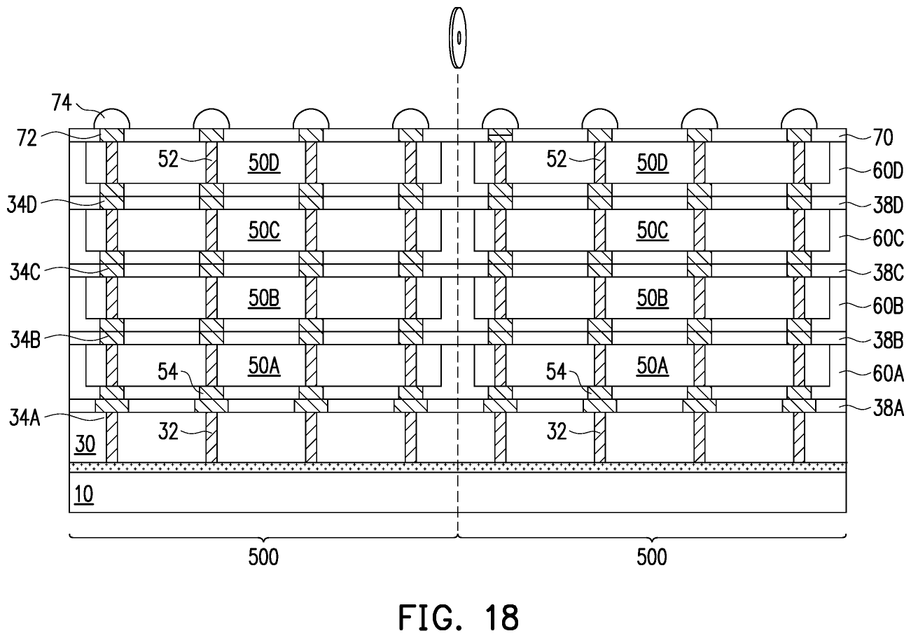

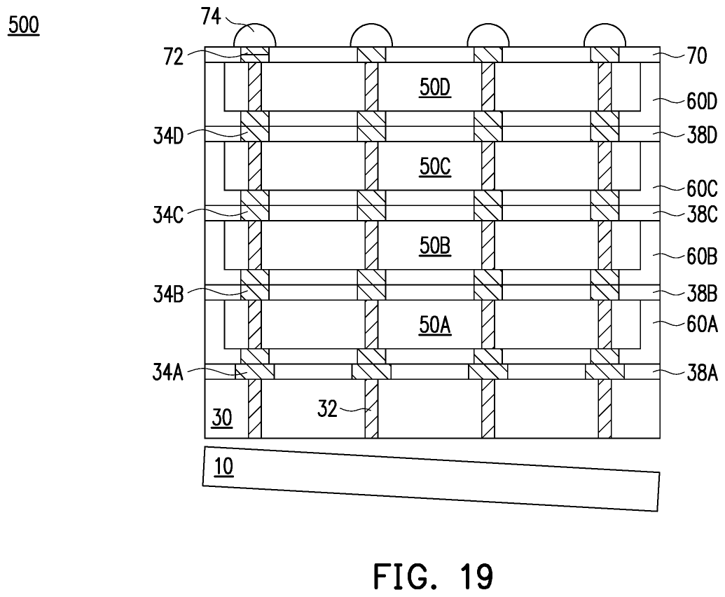

In some embodiments, such as illustrated below with respect to FIG. 19 the device die 30 may have through-vias which extend through or partially through a substrate of the device die 30. If extending partially through, a subsequent process may be used to thin the back side of the substrate of the device die 30 to expose the through-vias. This will be explained in greater detail with respect to the context of FIG. 19.

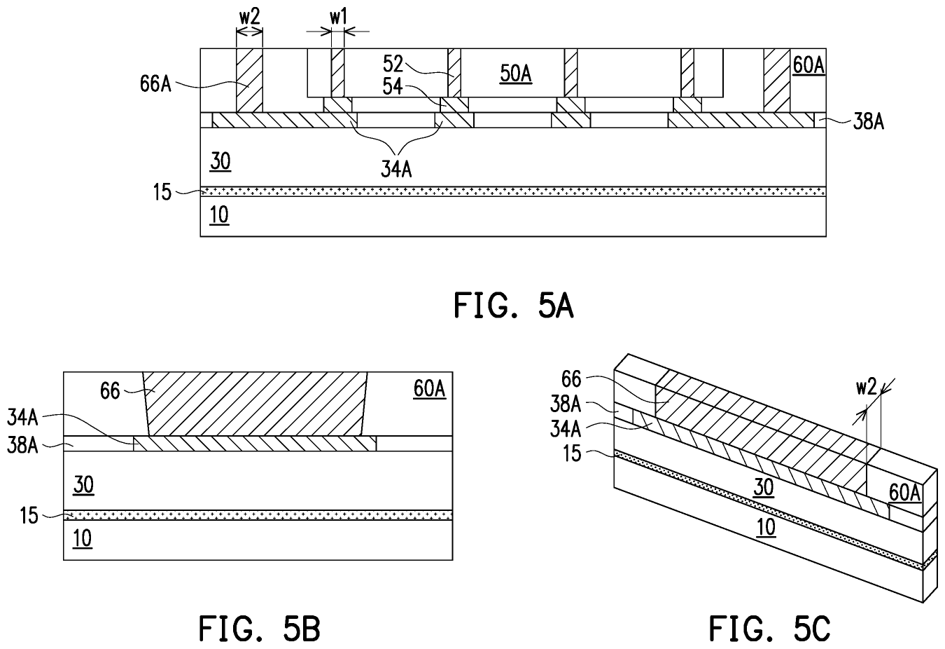

In FIG. 1, conductive features 34A may be formed over the device die 30 which are coupled to contact features (not shown) of the device die 30. The conductive features 34A may include metal lines and contact pads which may be used for bonding additional devices to the top of the device die 30. The conductive features 34A may be formed within an insulating layer 38A. Where the conductive features 34A include metal lines, the metal lines may run within the insulating layer 38A, and may, for example, run where a TDV wall 66 will be subsequently formed, such as illustrated below with respect to FIGS. 5A, 5B, and 5C. In other embodiments, the metal lines may cross perpendicular to a lengthwise direction of the subsequently formed TDV wall 66.

The insulating layer 38A may be formed using any suitable material and any suitable technique. In some embodiments the insulating layer may be made of silicon oxide, silicon nitride, silicon oxynitride, undoped Silicate Glass (USG), polyimide, polybenzoxazole (PBO), or the like. The insulating layer 38A may be deposited by any suitable technique, such as by PVD, CVD, spin-on, the like, or combinations thereof. The insulating layer 38A may then be patterned to form openings therein corresponding to the conductive features 34A. A photoresist may be formed over and the insulating layer 38A and patterned with the pattern of the openings to expose the portions of the insulating layer 38A to be removed. An etching process may be used to remove the exposed portions of the insulating layer 38A and form the openings in the insulating layer 38A. Then, a conductive material may be deposited in the openings. An ashing process may be used to remove the photoresist and excess conductive material and/or a planarization process such as a CMP process may be performed to remove the excess portions of the conductive material higher than the top surface of the insulating layer 38A, leaving the conductive features 34A in the openings. The conductive material may include a diffusion barrier and a copper-containing metallic material over the diffusion barrier. The diffusion barrier may include titanium, titanium nitride, tantalum, tantalum nitride, or the like. The conductive material may include a seed layer.

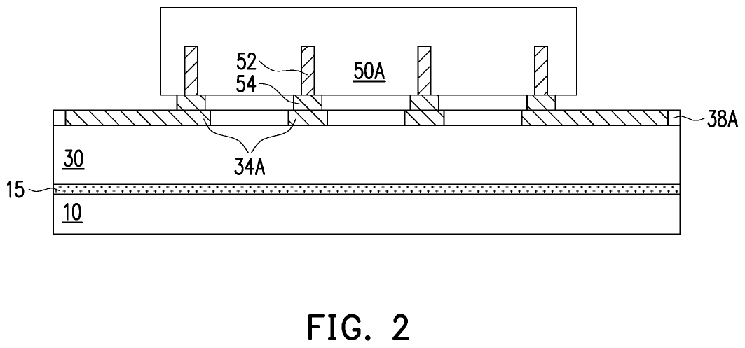

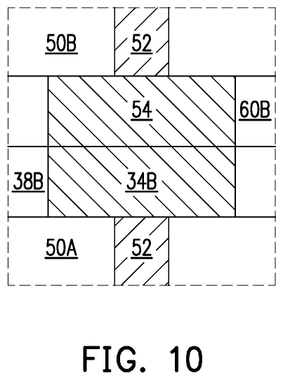

In FIG. 2, a device die 50A is bonded to the conductive features 34A by contact pads 54. The bonding may utilize any suitable process, such as that described below with respect to FIG. 10. The device die 50A may be any suitable device, including any of the candidate device types discussed above with respect to the device die 30. In some embodiments, the device die 50A is a memory die and is a first tier in a memory cube. As indicated in FIG. 2, the device die 50A may have through silicon vias (TSVs) 52 which protrude partially through the substrate of the device die 50A, which may be revealed during a subsequent process, as described below. In other embodiments, the TSVs 52 may traverse completely through the substrate of the device die 50A and may be exposed on the back side (the top side in the illustrated FIG. 2).

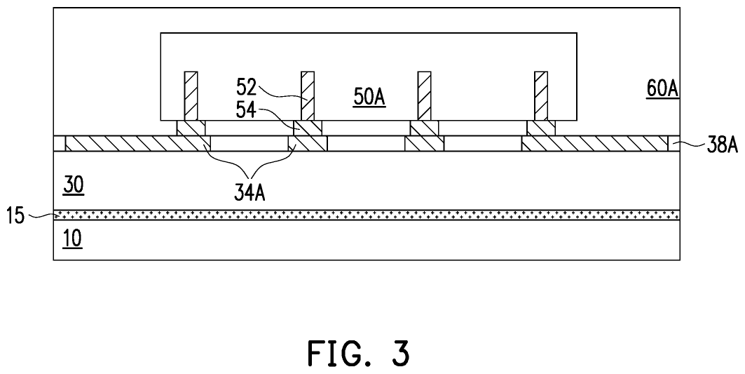

In FIG. 3, an encapsulant 60A is deposited over and laterally surrounding the device die 50A. In some embodiments, the encapsulant 60A may also extend below the device die 50A and laterally surround the contact pads 54. In other embodiments, a separate underfill may be used. In yet other embodiments, the face of the device die 50A may contact the face of the insulating layer 38 directly, such that there is no space between the device die 50A and the insulating layer 38. The encapsulant 60A may be any suitable fill material such as a dielectric material such as a resin, epoxy, polymer, oxide, nitride, the like, or combinations thereof, which may be deposited by any suitable process, such as by flowable CVD, spin-on, PVD, the like, or combinations thereof.

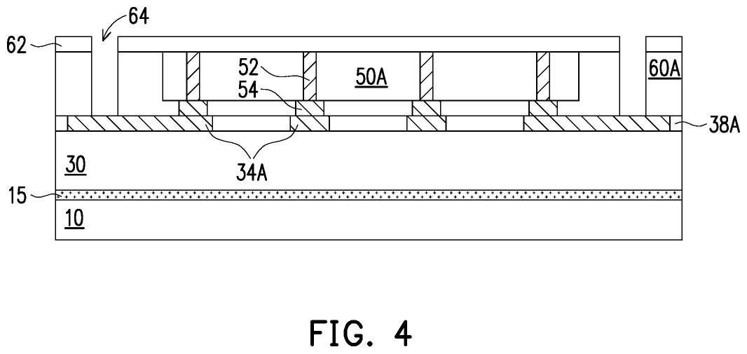

In FIG. 4, a planarization process may be used to level the upper surface of the encapsulant 60A with the upper surfaces of the device dies 50A. The planarization process may include a grinding and/or a chemical mechanical polishing (CMP) processes. The planarization process may be continued until the TSVs 52 are exposed through the substrate of the device die 50A. Next, openings 64 may be formed in the encapsulant 60A using a suitable photolithographic technique. For example, a photoresist layer 62 may be deposited over the encapsulant 60A and patterned to form openings corresponding to the openings 64, which are then transferred to the encapsulant 60A by an etching process. The openings 64 expose a portion of the conductive features 34A which are electrically coupled to one or more of the TSVs 52.

In FIG. 5A, a through die via (TDV) wall 66A is formed in the openings 64. The TDV walls 66A may be formed by depositing a conductive fill in the openings 64. The conductive fill may be deposited by any suitable process, such as by CVD, PVD, electroplating, electroless plating, and so forth, or combinations thereof. Prior to depositing the conductive fill include a diffusion barrier and/or seed layer may be deposited. The diffusion barrier may include titanium, titanium nitride, tantalum, tantalum nitride, or the like. The seed layer may include a copper containing material, deposited by sputtering, PVD, CVD, and so forth. Following deposition of the TDV wall 66A, the remaining photoresist 62 (if any) may be removed by an ashing or plasma removal process. A planarization process, such as a CMP process, may be used to level the upper surfaces of the device die 50A, TSVs 52, TDV wall 66A, and encapsulant 60A, thereby removing any excess conductive material from the conductive fill. The width w1 of the TSVs 52 may be between about 2 μm and 7 μm and the width w2 may be greater than about 15 μm, such as between about 12 μm and about 30 μm.

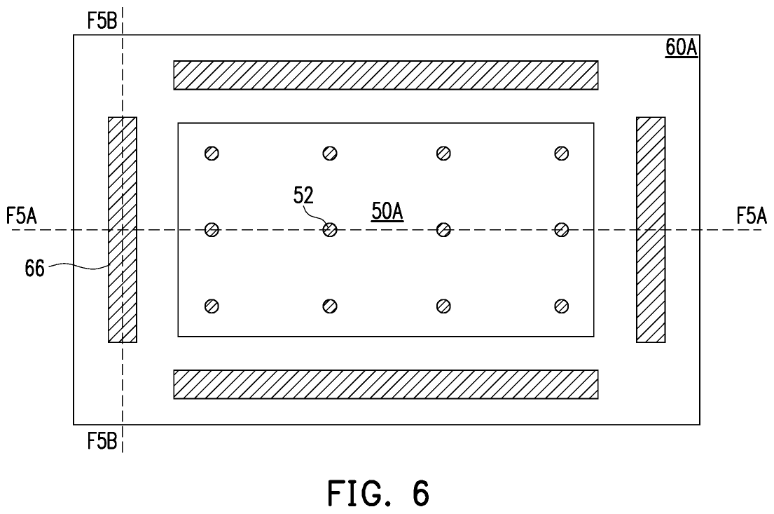

FIGS. 5A, 5B, and 5C illustrate various views of the TDV wall 66A, in accordance with some embodiments. FIG. 6 illustrates a top down view of the TDV wall 66A. As illustrated in FIG. 6, the TDV wall 66A may extend along one or more sides of the device die 50A. The dashed line F5A-F5A shows a cross-sectional reference line for the structure illustrated in FIG. 5A. The dashed line F5B-F5B shows a cross-sectional reference line for the structure illustrated in FIG. 5B. FIG. 5C illustrates a perspective view of the TDV wall 66A in accordance with some embodiments.

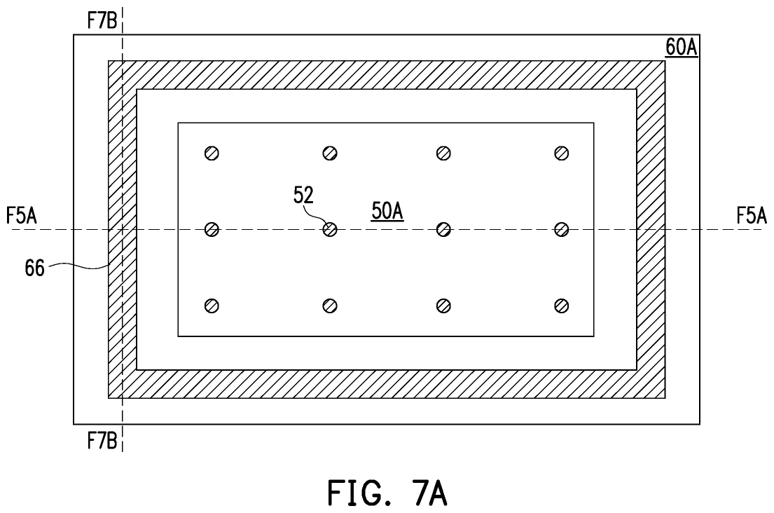

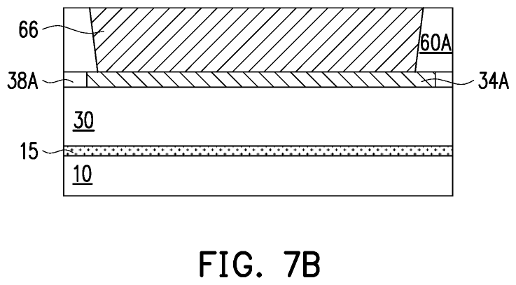

FIGS. 7A and 7B illustrate various views of the TDV wall 66A, in accordance with other embodiments. FIG. 7A illustrates a top down view of the TDV wall 66A, of another embodiment which illustrates that the TDV wall 66A may circumnavigate the device die 50A. The dashed line F5A-F5A of FIG. 7 shows a cross-sectional reference line for the structure illustrated in FIG. 5A. The dashed line F7B-F7B shows a cross-sectional reference line for the structure illustrated in FIG. 7B.

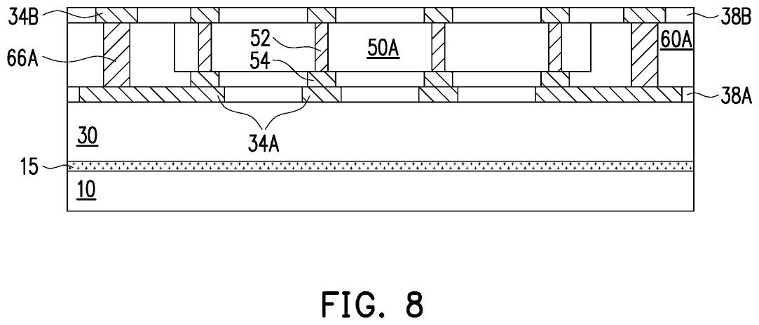

In FIG. 8, conductive features 34B are formed over the TSVs 52 of the device die 50A in an insulating layer 38B. In some embodiments, the conductive features 34B may also be formed over the TDV wall 66A. The insulating layer 38B and conductive features 34B may be formed using processes and materials similar to those described above with respect to the insulating layer 38A and conductive features 34A. In embodiments which include the conductive features 34B over the TDV wall 66A, such conductive features 34B may include distinct via type structures through the insulating layer 38B or may include a ring-like structure or metal line extending along a lengthwise direction of the TDV wall 66A.

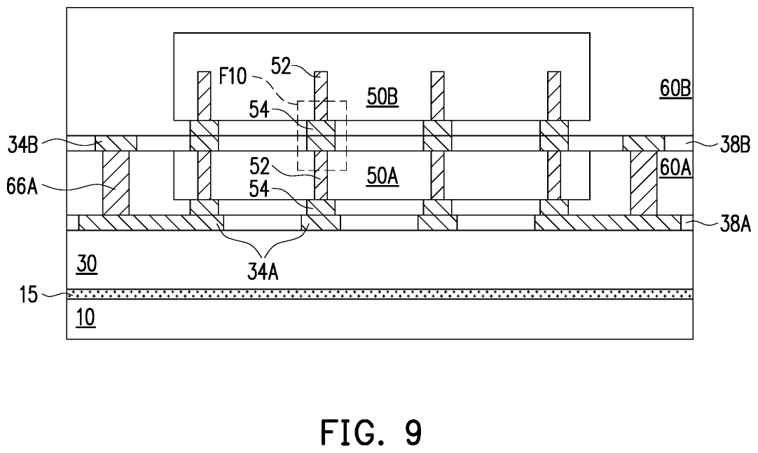

In FIG. 9, a device die 50B is bonded to the conductive features 34B by contact pads 54 of device die 50B. The device die 50B may be any suitable device, including any of the candidate device types discussed above with respect to the device die 30. In some embodiments, the device die 50B is a memory die and is a second tier in a memory cube. The bonding process is further described below with respect to FIG. 10. After bonding the device die 50B, an encapsulant 60B is deposited over and laterally surrounding the device die 50B, using processes and materials similar to those used to form the encapsulant 60A. In some embodiments, the encapsulant 60B may also extend below the device die 50A and laterally surround the contact pads 54. In other embodiments, a separate underfill may be used.

FIG. 10 illustrates a bonding mechanism which may be used to bond the device die 50B to the device die 50A (or the device die 50A to the device die 30, as noted above). Other suitable bonding mechanisms may be used. In FIG. 10, the protruding contact pads 54 may be aligned to the conductive features 34B and a metal-to-metal bond formed between the two by a pressing and annealing process which causes metal from each of the contact pads 54 and the conductive features 34B to interdiffuse to the other.

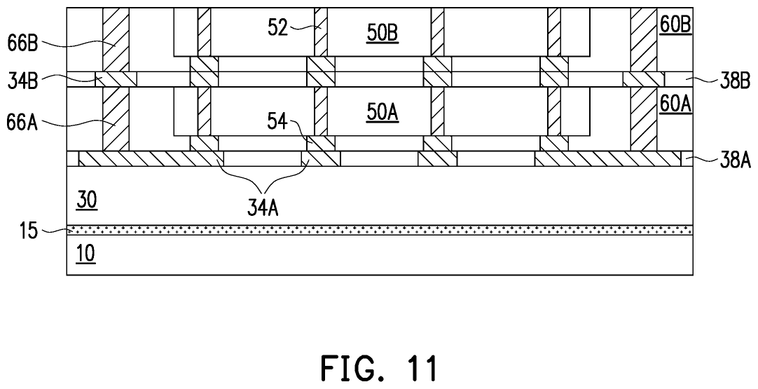

In FIG. 11, a planarization process may be used to level the upper surface of the encapsulant 60B with the upper surfaces of the device die 50B. The planarization process may include a grinding and/or a chemical mechanical polishing (CMP) processes. The planarization process may be continued until the TSVs 52 are exposed through the substrate of the device die 50A. Next, a TDV wall 66B may be formed in the encapsulant 60B using processes and materials similar to those used to form the TDV wall 66A. In some embodiments, the opening for the TDV wall 66B may extend through the insulating layer 38B to expose the TDV wall 66A and the TDV wall 66B may come in direct contact with the TDV wall 66A. In other embodiments, such as illustrated in FIG. 11, the opening for the TDV wall 66B may expose conductive features 34B formed over the TDV wall 66A, which are then used to electrically couple the TDV wall 66B to the TDV wall 66A.

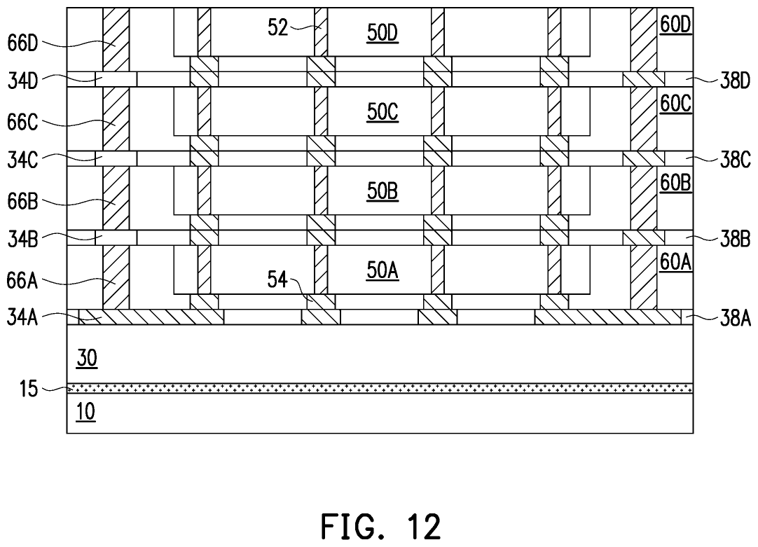

In FIG. 12, the process of adding device dies and TDV walls may be continued until a desired number of device dies have been added. In the illustrated embodiment, device dies 50C and 50D are added along with TDV walls 66C and 66D. These result in like features labeled with like numbers with a separate lettered tier designation. It should be appreciated that any number of tiers may be added, each tier including additional device dies.

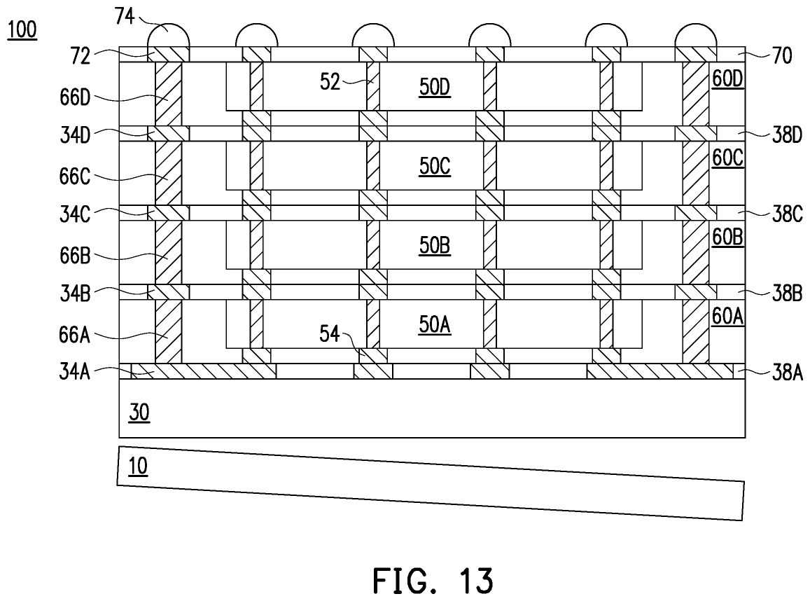

In FIG. 13, an insulating layer 70 and under bump metallizations (UBMs) 72 are added over the device die 50D and TDV wall 66D. The insulating layer 70 and UBMs 72 may be formed using processes and materials similar to those discussed above with respect to the insulating layer 38A and conductive features 34A, respectively. Connectors 74 may be formed on each of the UBMs 72 using any suitable technique such as solder printing, ball placement, ball stencils, and so forth. UBMs and passivation layers (not shown) may also be used in the formation of the connectors 74. In some embodiments, the connectors 74 may be microbumps, controlled collapse chip connector (C4) bumps, ball grid array (BGA) balls, or the like. A reflow may be used to adhere the connectors 74 to the UBMs 72, in some embodiments. Following forming the connectors 74, a carrier substrate de-bonding is performed to detach (or “de-bond”) the carrier substrate 10 from the front side of the device dies 30. In accordance with some embodiments, the de-bonding includes projecting a light such as a laser light or an UV light on the release layer 15 so that the release layer 15 decomposes under the heat of the light and the carrier substrate 10 can be removed, thereby forming the 3DIC package 100.

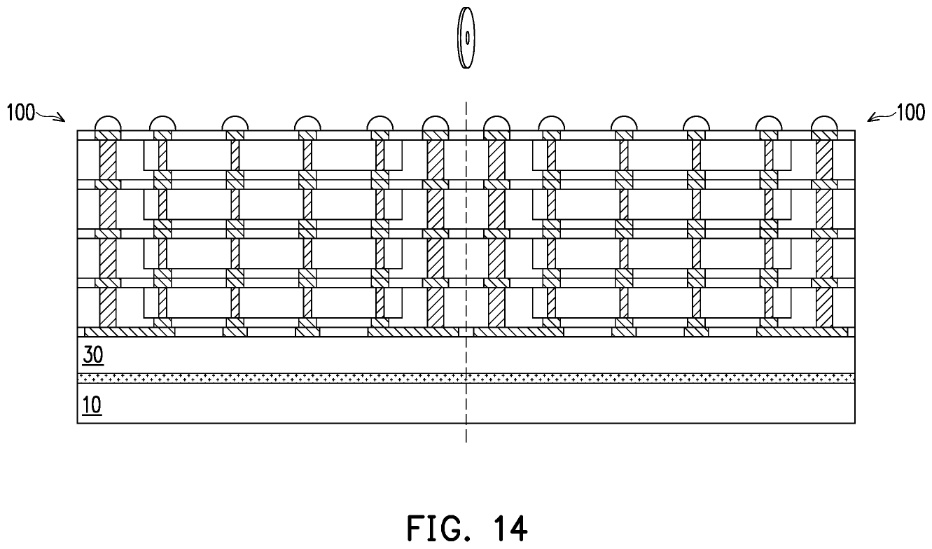

In FIG. 14, an embodiment is illustrated in which several 3DIC packages 100 are formed simultaneously on the carrier substrate 10. After the connectors 74 are formed, the carrier substrate 10 may be detached and the structure may then be flipped over and placed on a tape (not shown). A dicing process may be used to singulate each package 100 from each other, thereby forming the 3DIC package 100. The dashed lines represent dicing lines where the packages 100 are separated. The singulation process used to singulate the packages may be any suitable process, such as using a die saw, a laser cutting, or the like to cut through the multi-package structure to release each of the packages 100.

In FIG. 15, the 3DIC package 100 is mounted to an interposer 200. In some embodiments, the interposer 200 includes a substrate 215, a front-side dielectric layer 217 with contact pads 219, a backside dielectric layer 221 with contact pads 223, and conductive paths 225 through the thickness of the substrate coupling the contact pads 223 at the back side to contact pads 219 at the front side. In the example of FIG. 15, the interposer 200 also has a plurality of conductive bumps 220 at its front-side. The conductive bumps 220 are electrically coupled to the conductive paths. The conductive bumps 220 may be a copper pillar or a solder region, for example.

The connectors 74 (see FIG. 13) of the package 100 may be attached to corresponding contact pads 223 on the interposer 200. An underfill material 205 may be deposited under the package 100 and around the connectors 74. Example materials of the underfill material 205 include, but are not limited to, polymers and other suitable non-conductive materials. The underfill material 205 may be dispensed in the gap between the interposer 200 and the package 100 using, e.g., a needle or a jetting dispenser. A curing process may be performed to cure underfill material 205. In some embodiments of the package 100, a separate underfill between device dies 50 or device die 50A and 30 may be used, such as referenced above with respect to FIG. 3; in such embodiments, the underfill material used may be similar to the underfill material 205.

After the underfill material 205 is formed, a molding material 210 is formed around the package 100, such that the package 100 is embedded in the molding material 210. The molding material 210 may include an epoxy, an organic polymer, a polymer with or without a silica-based or glass filler added, or other materials, as examples, and may be deposited using a compression process or other suitable process. In the example of FIG. 15, sidewalls of the molding material 210 are aligned with respective sidewalls of the interposer 200. The structure illustrated in FIG. 15 may be referred to as a Chip-On-Wafer (CoW) structure, and the device formed is referred to as the CoW device 250.

In FIG. 16, the CoW device 250 is attached to a substrate 260 by the conductive bumps 220. An underfill material 251 may be dispensed in the gap between the CoW device 250 and the substrate 260. The underfill material 251 may be formed using processes and materials used for forming the underfill material 205. In some embodiments, the substrate 260 includes a silicon substrate 252, a front-side dielectric layer 253 with contact pads 254, a backside dielectric layer 256 with contact pads 257, and conductive paths 255 through the thickness of the substrate coupling the contact pads 257 at the back side to contact pads 254 at the front side. In the example of FIG. 16, the substrate 260 also has a plurality of conductive bumps 259 at its front-side. The conductive bumps 259 are electrically coupled to the conductive paths 255. The conductive bumps 259 may be a copper pillar or a solder region, for example. In some embodiments, active and/or passive devices 258 may be formed in the substrate 252 and may include for example, resistors, capacitors, inductors, transistors, and so forth.

The structure illustrated in FIG. 16 may be referred to as a Chip-on-Wafer-on-Substrate (CoWoS) structure, and the device, along with the heat dissipation elements described below is referred to as the CoWoS device 300.

After the underfill material 251 is formed heat dissipation features may be attached to the CoW device 250 and attached to the substrate 260. The heat dissipation features may include a lid 275, thermal interface materials 270 and 280 and heat spreader 285. The lid 275 may be used to help dissipate heat from the CoW device 250. The lid 275 may be adhered to the substrate by adhesive pads or adhesive material 265. The lid 275 may interface with the CoW device 250 by a thermal interface material (TIM) 270. The TIM 270 may be deposited on top of the CoW device 250 prior to placing the lid 275 over the CoW device 250. The TIM 270 may instead or in addition be deposited on the underside of the CoW device 250.

The TIM 270 is a material having a good thermal conductivity, which may be greater than about 5 W/m*K, and may be equal to, or higher than, about 50 W/m*K or 100 W/m*K. For example, the TIM 270 may be a polymer formed to a thickness between about 10 μm and 100 μm, though other thicknesses are contemplated and may be used. The lid 275 may be attached by the adhesive pads or adhesive material 265 and by the TIM 270 which may also have adhesive qualities. In some embodiments, the adhesive pads or adhesive material 265 may include, for example, solder or another suitable material. Because the TIM 270 contacts the device die 30 of the CoW device 250, it can more effectively transfer heat from the device die 30 of the CoW device 250 which may produce more heat than the device dies 50A/50B/50C/50D/etc.

The lid 275 has a high thermal conductivity and may be formed using a metal, a metal alloy, or the like. For example, the lid 275 may comprise a metal, such as Al, Cu, Ni, Co, and the like, or an alloy thereof. The lid 275 may also be formed of a composite material selected from the group consisting of silicon carbide, aluminum nitride, graphite, and the like.

A heat spreader 285 may be attached to the lid 275 by a TIM 280. The TIM 280 may be formed using processes and materials that are the same as or similar to the TIM 270. The heat spreader 285 may be made of a material having high thermal conductivity and may include a base portion 285b and fin portions 285f, the fin portions 285f radiating heat provided to the fin portions 285f from the base portion 285b.

In FIG. 17, the CoWoS device 300 may be attached to a printed circuit board (PCB) 350 by the conductive bumps 259 (see FIG. 16) of the CoWoS device 300. A power chip 320 may also be attached to the PCB 350. The power chip 320 may, for example, be a voltage regulator and provide regulated power to the CoWoS device 300. An example power routing is shown through the CoWoS device 300. As illustrated in FIG. 17, the power routing has a power plane through the TDV walls 66 and through the TSVs 52, sequentially. Because the CoW device 250 utilizes the TDV walls 66 for power management, the internal resistance of the CoW device 250 is reduced, causing less waste heat generation from excessive resistance. The TDV walls 66 also provide good heat transfer through the layers of the CoW device 250 to the heat dissipating features, such as the lid 275 and heat spreader 285. Also, because the power is routed in the TDV walls 66, the heat which is generated from the internal resistance of the TDV walls 66 is not transferred to the device dies 50A, but rather has a heat dissipation path through the device die 30, which has a large interface with the TIM 270 for efficient heat dissipation.

FIGS. 18 through 19 illustrate the formation of a 3DIC package 500, in accordance with some embodiments. Except as noted below, the structure in FIG. 18 may be formed using processes and materials similar to those used with respect to the FIGS. 1 through 14, with like references referring to like features. Rather than form the TDV walls 66, the 3DIC package 500 as illustrated in FIG. 18 omits these structures, in favor of adding TSVs 32. The TSVs 32 may be aligned to the TSVs 52 and may be already existing in the device die 30 or may be added using a patterning, etching, and deposition process which uses processes and materials similar to those described above with respect to forming the TDV walls 66. The TSVs 32 may extend all the way through the device die 30, or may extend only partially through the device die 30, and a subsequent process used to thin the device die 30 from the reverse side and expose the TSVs 32.

FIG. 18 illustrates that, similar to FIG. 14, several of the 3DIC packages 500 may be formed at the same time on the carrier substrate 10 and then singulated to form individual 3DIC packages 500.

In FIG. 19, the carrier substrate 10 is removed by a debonding process, such as described above. It should be noted that, in some embodiments, the carrier substrate 10 may be removed and the structure flipped over prior to singulation, while in other embodiments, the singulation may occur prior to the carrier debonding.

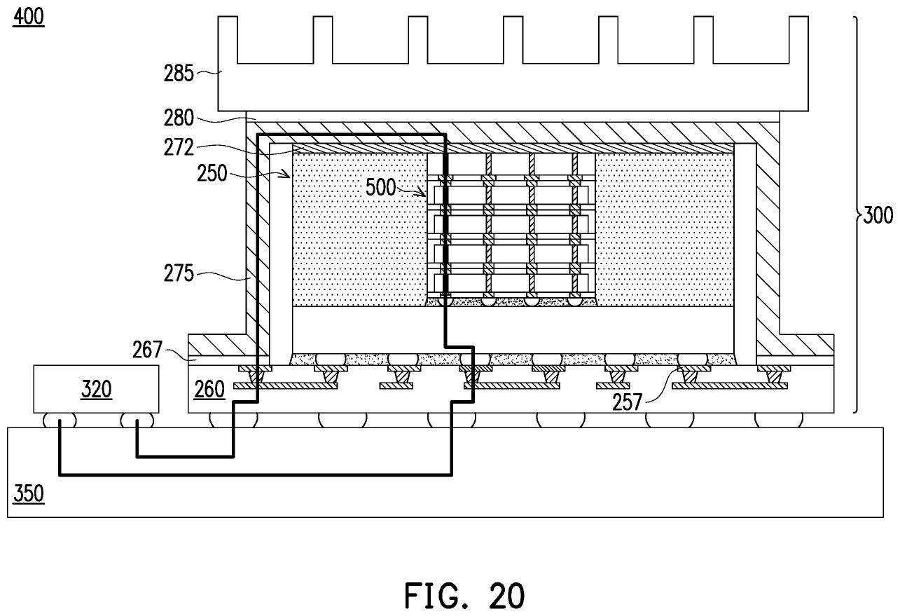

FIG. 20 illustrates a structure 400 which includes CoWoS device 300 attached to the PCB 350 in a manner similar to that described above with respect to FIG. 17, with like references being used to illustrate like structures. In the CoWoS device 300 of FIG. 20, however, rather than use the TDV wall 66, the lid 275 is used as a power plane. In such embodiments, the material of the lid is selected to be a conductive material from the above-listed candidate materials. The lid 275, being a bulky metal can transfer power efficiently. An example power routing is shown through the CoWoS device 300 of FIG. 20. As illustrated in FIG. 20, the power routing has a power plane through the lid 275 and through the TSVs 52, sequentially. Because the CoWoS device 300 utilizes the lid 275 for power management, the internal resistance of the CoWoS device 300 is reduced, causing less waste heat generation from excessive resistance. The lid 275 also provides good heat transfer from the layers of the CoW device 250 to the heat dissipating features, including the lid 275 itself and the heat spreader 285. Also, because the power is routed in the lid 275, the heat which would have been generated from the internal resistance of the vias 52 is lessened and therefore not transferred to the device dies 50A, 50B, 50C, 50D, etc., which has a large interface with the TIM 270 for efficient heat dissipation.

To achieve the power routing in the lid 275, there are some differences in the CoWoS device 300 of FIG. 20 over the similar structure of FIG. 17. The 3DIC package 500 is used in the CoW device 250, which includes TSVs 32 through the device die 30, the lid 275 is physically and electrically coupled to the CoW device 250 through a conductive material 272 which interfaces with the TSVs 32 and the lid 275, and the lid 275 is physically and electrically coupled to the substrate 260 through a conductive material 267.

Except for these changes, the CoW device 250 and CoWoS device 300 may be formed using processes and materials similar to those used to form the CoW device 250 of FIG. 15 and CoWoS device 300 of FIG. 16, respectively. For example, the CoW device 250 may be formed using the same processes and materials of that of the CoW device 250, except the device die 30 has TSVs 32 formed therein, such as noted above. Also, when forming the CoW device 250 of FIG. 20, if the TSVs 32 (see FIG. 18) have not been exposed in the device die 30, a grinding or planarization process may be used to thin the device die 30 from the top side to expose the TSVs 32, for example, after forming the molding material 210. With respect to the CoWoS device 300, the process of attaching the lid to the CoW device 250 and to the substrate 260 may be altered by using the conductive material 267 instead of the adhesive 265 and using the conductive material 272 instead of the TIM 270. Accordingly, the lid 275 may be electrically coupled to a contact pad 257 (see FIG. 16) of the substrate 260 and to the TSVs 32 (see FIG. 19) of the device die 30.

In some embodiments, the conductive material 267 and the conductive material 772 may be deposited on the underside of the lid 275 prior to attaching the lid 275 to the CoW device 250 and substrate 260. And in other embodiments, the conductive material 267 and/or the conductive material 272 may be deposited on the substrate 260 or CoW device 250 prior to attaching the lid 275. The conductive material 267 and conductive material 272 may be any suitable conductive material. For example, in some embodiments, the conductive material 267 and 272 may each be a solder-based material, such as a solder paste which is deposited on the lid 275 and/or the CoW device 250 and/or the substrate 260, and then when the lid 275 is attached, the solder paste reflowed to complete the attachment. Other solder materials may be used as well. The thickness of the conductive material 272 may be between about 10 μm and about 100 μm, though other thicknesses are contemplated. Other conductive materials may be used for the conductive materials 267 and 272, such as nickel or the like. In some embodiments, the lid 275 may be adhered to the substrate 360 with a combination of the adhesive 265 and the conductive materials 267, the adhesive 265 adjacent the conductive materials 267, which is disposed over and in contact with one or more of the contact pads 257.

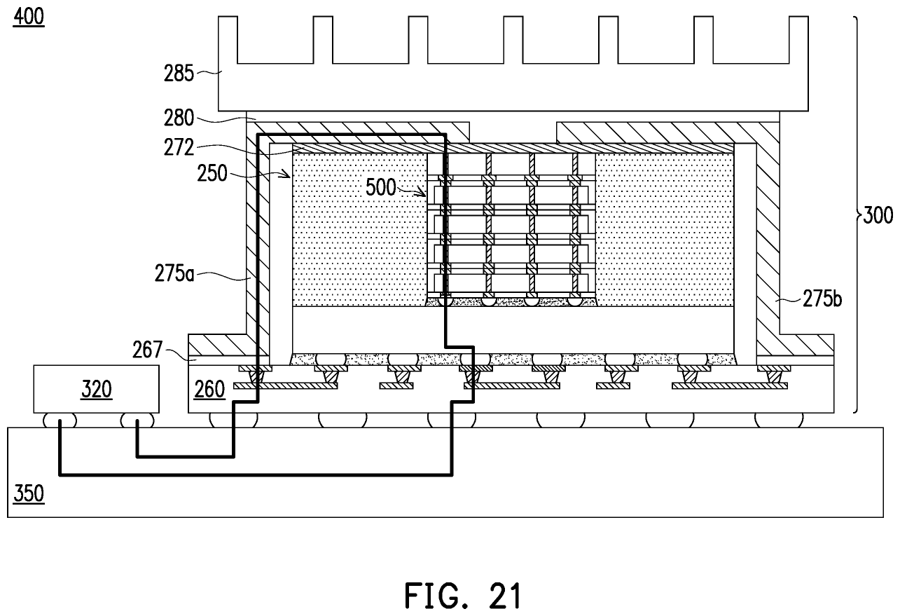

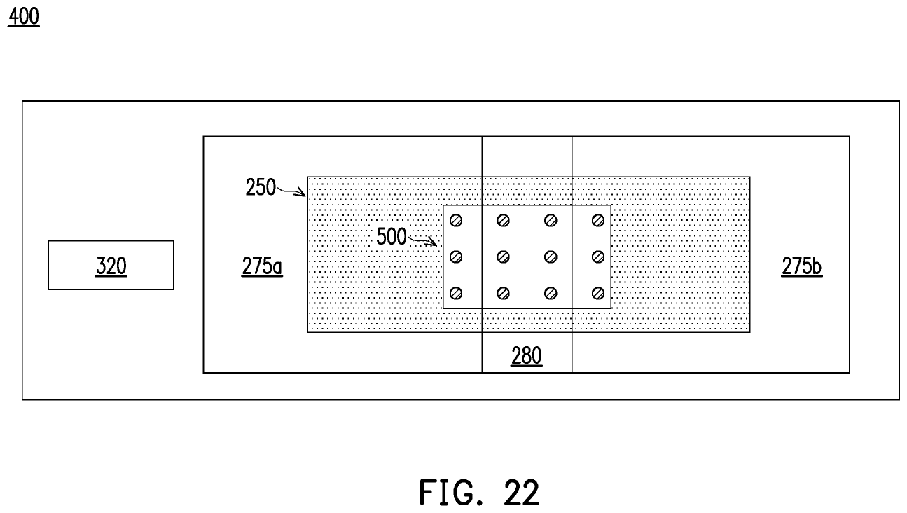

FIGS. 21 and 22 illustrate a structure 400 which is similar to the structure 400 of FIG. 20, except the lid 275 used may be split, so that part of the lid 275a may act as a first power plane, while the other part of the lid 275b may be electrically floating (not attached to any electrical signal) or may act as a second power plane, which may be electrically separated from the first power plane. The lid 275a and 275b may be attached using the processes and materials described above with respect to FIG. 20. In some embodiments, the lid 275a may be attached at the same time and in the same process as the lid 275b, while in other embodiments, the lid 275a may be attached in a separate process than attaching the lid 275b. In FIG. 22, a top down view is illustrated of the structure in FIG. 21, without the heat spreader 285. The lid 275a and the lid 275b are illustrated, as well as the TIM 280. The CoW device 250 is illustrated as well as the 3DIC package 500, for context, but which would not otherwise be visible in this view.

It should be noted that, although the 3DIC package 500 is used in the structures of FIGS. 20 through 22, the 3DIC package 100 may be used instead, if the device die 30 includes the TSVs 32. Then, the structures 400 in each of FIGS. 17, 20, and 21 may be combined in a similar structure which combines the power plane provided by the TDV walls 66 with the power plane provided by the lid 275, so that multiple power planes may be used.

The embodiments illustrated in FIGS. 1 through 22 provide advantages of running power planes which reduce internal resistance and waste heat generation through the device dies 30, 50A, 50B, 50C, 50D, etc. to provide more efficient power transfer. Also, because the device die 30 is located at the top of the die stack, proximate to the heat dissipation features, the heat dissipation from the device die 30 to the heat dissipation features is more efficient than if the device die 30 were located at the bottom of the die stack.

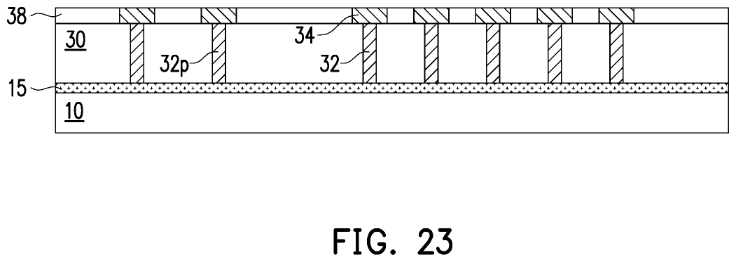

FIGS. 23 through 35D illustrate intermediate views of forming power planes in accordance with other embodiments which utilize a dummy die. It should be understood that these embodiments may be formed using similar processes and materials as those described above, unless otherwise noted. Like references are used to refer to like elements. The embodiments in FIGS. 23 to 35D dispose the device die 30 beneath the device dies 50A, 50B, 50C, 50D, etc. The heat dissipation features are omitted from the illustrated embodiments, however, it should be understood that heat dissipation features may optionally be utilized.

In FIG. 23, a device die 30 is bonded to a carrier substrate 10 using the release layer 15. The device die 30 has TSVs 32 that traverse through the thickness of the device die 30. In some embodiments, the TSVs 32 may only traverse partially through the substrate of the device die 30 and may be revealed by a subsequent process. The TSV 32p is separately labeled as corresponding to the TSVs 32 which are utilized by the dummy die to provide a power plane to the device dies. Insulating layer 38 is formed over the device die 30 and bond pads 34 are formed with in the insulating layer 38.

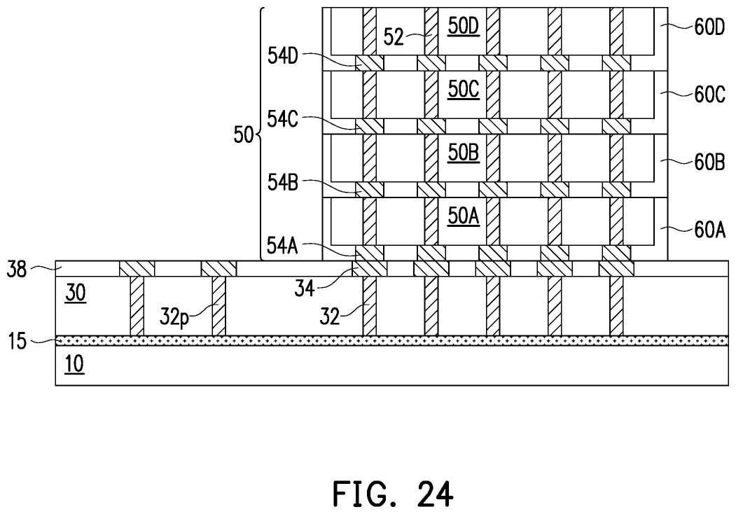

In FIG. 24, a die cube 50 is bonded to the device die 30 using an acceptable bonding process, such as described above with respect to FIG. 10. The die cube 50 may contain multiple device dies, such as device die 50A, 50B, 50C, and 50D, as illustrated. The die cube 50 may be encapsulated in an insulating material, such as the encapsulant 60A, 60B, 60C, and 60D, which may be artifacts of the process of forming the die cube 50. For example, the die cube 50 may be formed by a process similar to forming the stacked device dies 50A, 50B, 50C, and 50D, described above with respect to FIGS. 1 through 14, including a repeated process of bonding one die at a time, depositing a lateral encapsulant/fill, thinning the die, and forming bond pads between each tier of the dies, such as the bond pads 54A, 54B, 54C, and 54D. Other processes may be used for forming the die cube 50.

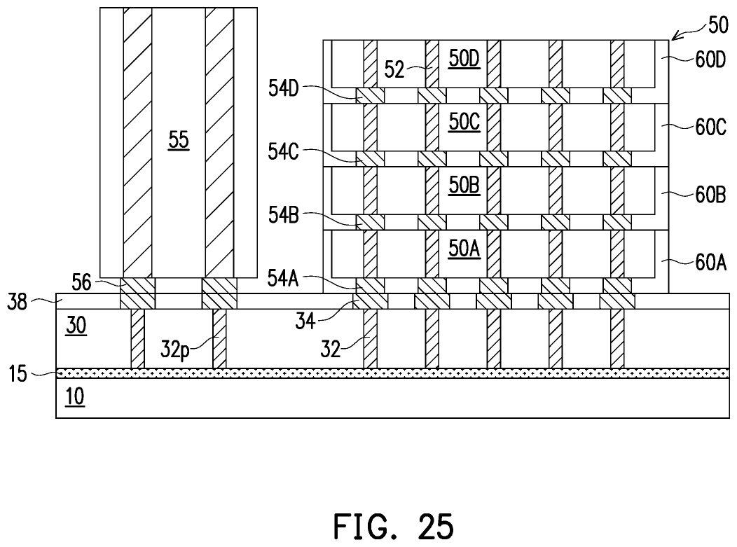

In FIG. 25, a dummy die 55 is bonded to the device die 30 by the bond pads 56. The bonding process may be as described above with respect to FIG. 10. The dummy die 55 may be taller or shorter than the die cube 50.

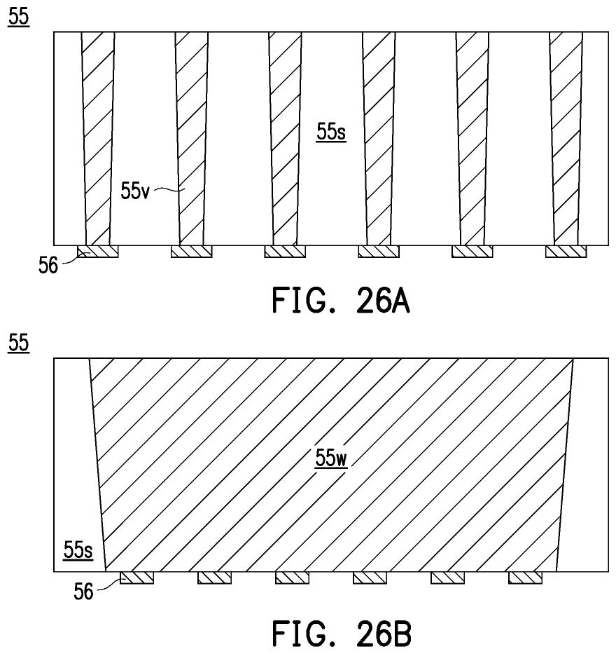

FIGS. 26A and 26B illustrate perpendicular cross sections of two different configurations of the dummy die 55. In FIG. 26A, multiple TDVs 55v may be formed through the substrate 55s of the dummy die 55. The substrate 55s may be a silicon containing substrate, such as bulk silicon or silicon oxide, a ceramic, and so forth. The TDVs 55v may be formed by an etching and filling process, such as described above. The bond pads 56 may be recessed into the substrate 55s or may protrude, such as illustrated in FIG. 26A. The dummy die 55 may be formed on a wafer and singulated therefrom, using wafer bonding and singulation processes such as those discussed above. In FIG. 26B, a TDV wall 55w may be formed instead of distinctive TDVs 55v. The TDV wall may be formed in the substrate 55s using processes and materials such as those discussed above with respect to the TDV walls 66. The bond pads 56 are shown as being discrete bond pads, however, in some embodiments, the bond pads 56 may be configured to be a long bond pad running the length of the bottom of the TDV wall 55w.

In FIG. 27, a non-conductive fill material 61 is formed over and around the die cube 50 and the dummy die 55. The non-conductive fill material 61 may include any suitable insulating materials formed using processes and materials such as those used to form the encapsulant 60A, described above with respect to FIG. 3.

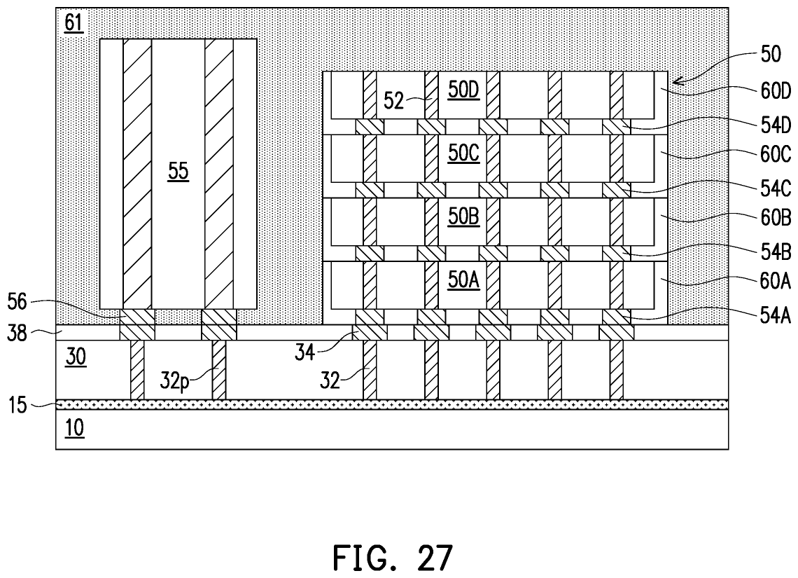

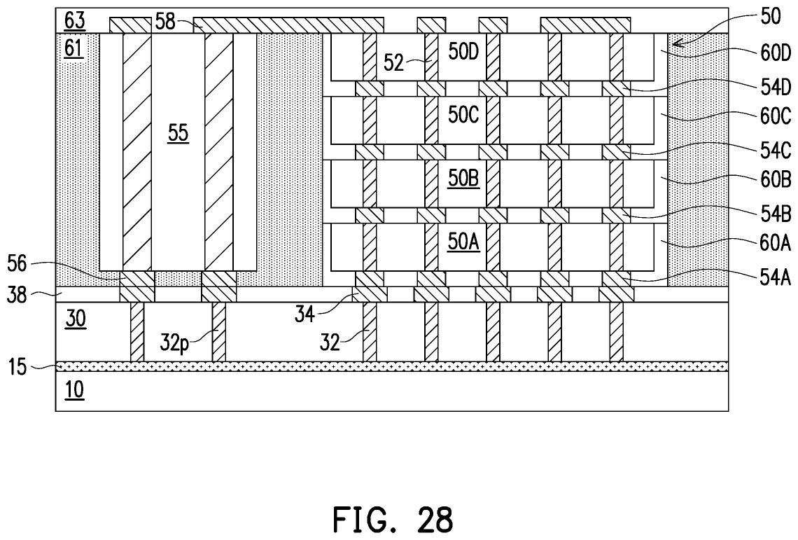

In FIG. 28, a planarization process, such as a CMP process may be used to level the upper surfaces of the fill material 61, the dummy die 55, and the die cube 50. Then, metal lines 58 may be formed in an insulating layer 63. In some embodiments, the metal lines 58 are formed first, for example, using a photoresist as a deposition template, and then the insulating layer 63 formed thereover, using for example a spin-on process or other suitable process. In other embodiments, the insulating layer 63 may be formed first and the metal lines formed using, for example, a damascene process. The metal lines 58 couple the TDVs 55v or TDV walls 55w in the dummy die 55 to the die cube 50, thereby providing a power plane for a subsequently formed device using the structure in FIG. 28.

In FIG. 29, a supporting substrate 65 may be bonded to the upper surfaces of the insulating layer 63. The supporting substrate 65 has great flexibility as to bonding and material composition. In some embodiments, the supporting substrate 65 may be any of the candidate materials for the carrier substrate 10, a semiconductor substrate, a bulk metal substrate, a metal alloy substrate, and so forth. In some embodiments, the supporting substrate 65 may be attached by an adhesive or a thermal interface material, such as a polymer.

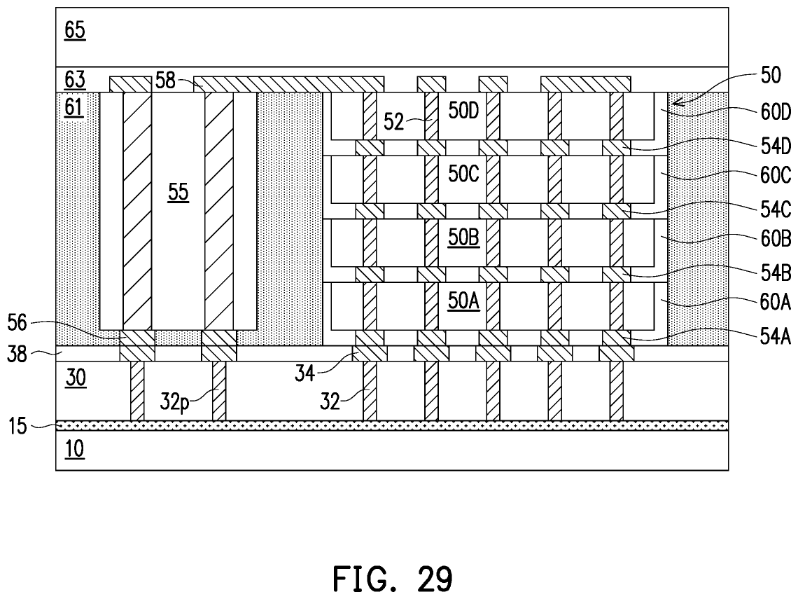

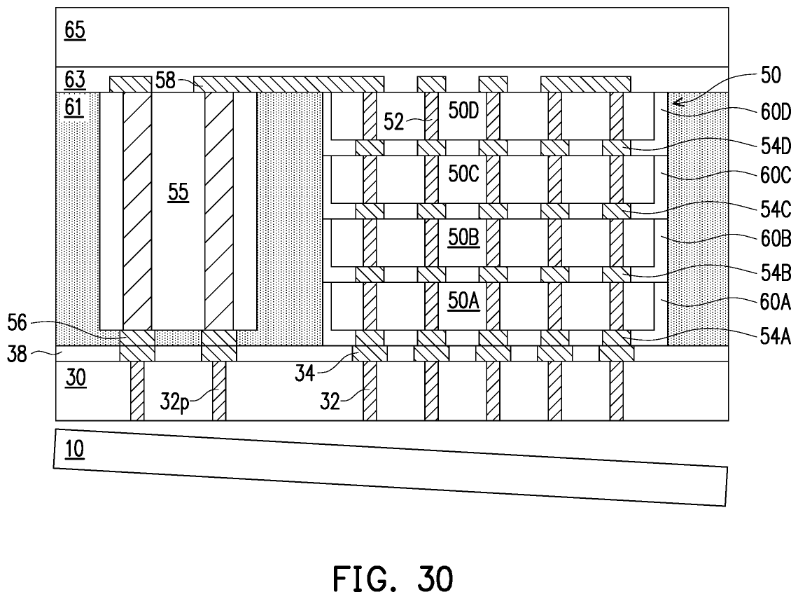

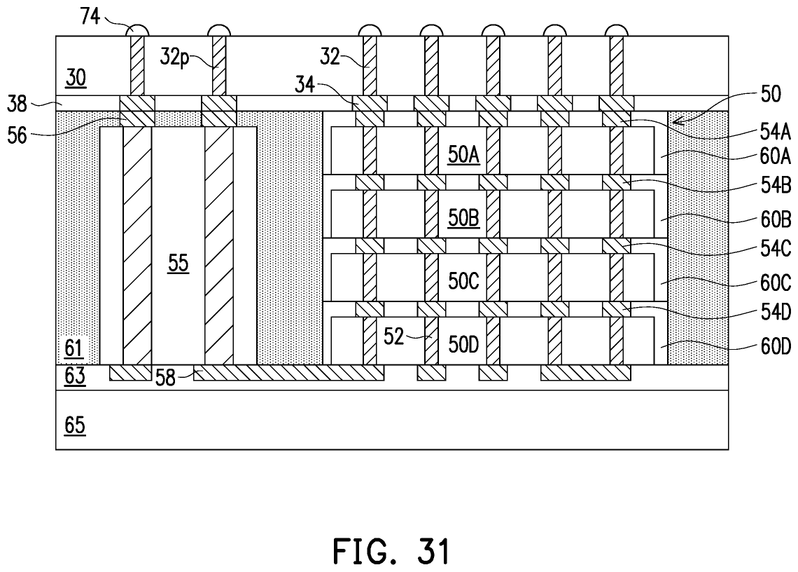

In FIG. 30 the carrier substrate 10 is removed by a debonding process and the structure of FIG. 30 is flipped and mounted on a tape (not shown). In FIG. 31, connectors 74 may be formed at a back surface of the device die 30. In some embodiments, the device die 30 may be thinned first, for example by a CMP process, to expose any buried TSVs 32 and 32p. FIG. 31 illustrates a completed 3DIC package 600.

It should be understood that in some embodiments, multiples of the 3DIC package 600 may be formed at the same time on a larger substrate and then singulated, to release individual 3DIC packages 600, similar to that described above with respect to FIG. 14.

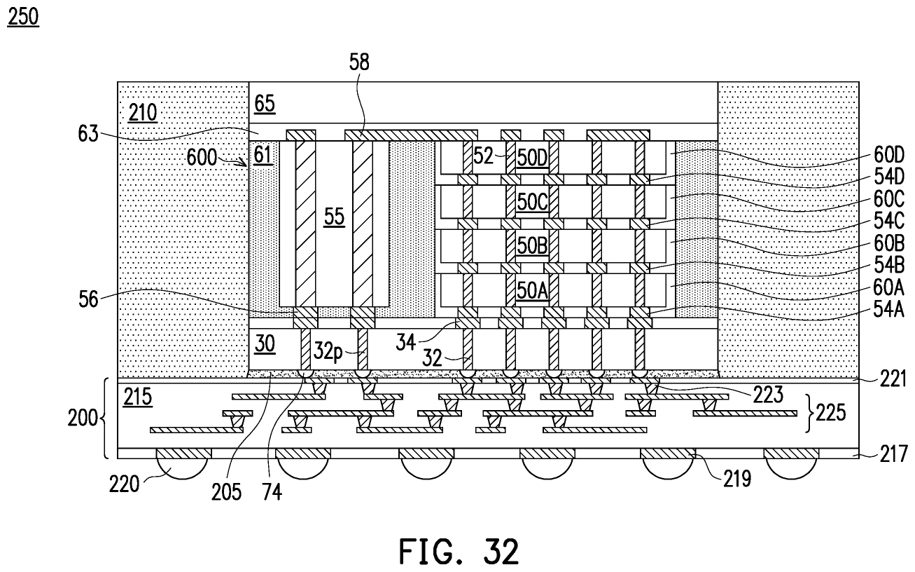

In FIG. 32, the 3DIC package 600 is mounted to the interposer 200. The connectors 74 of the package 600 may be attached to corresponding contact pads 223 on the interposer 200. An underfill material 205 may be deposited under the package 100 and around the connectors 74. After the underfill material 205 is formed, a molding material 210 is formed around the 3DIC package 600, such that the package 600 is embedded in the molding material 210. The structure illustrated in FIG. 32 may be referred to as a Chip-On-Wafer (CoW) structure, and the device formed is referred to as the CoW device 250.

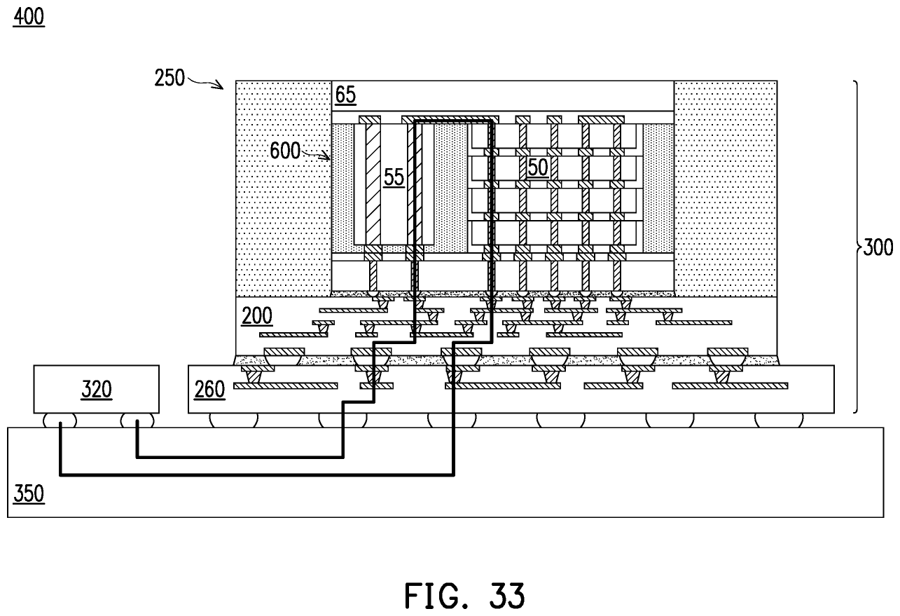

As referenced in FIG. 33, a structure 400 is formed, in accordance with some embodiments. The CoW device 250 may be attached to a substrate in a similar manner as described above with respect to FIG. 16 to form a CoWoS device 300. The CoWoS device 300 may then be attached to PCB 350. The power chip 320 may provide regulated power to the CoWoS device 300. An example power routing is shown through the CoWoS device 300. As illustrated in FIG. 33, the power routing has a power plane through the dummy die 55, and through the TSVs 52, sequentially. Because the CoW device 250 utilizes the dummy die 55 for power management, the internal resistance of the CoW device 250 is reduced, causing less waste heat generation from excessive resistance. The dummy die 55 also provides good heat transfer through the CoW device 250, which may radiate to heat dissipating features and/or through the substrate 260 and PCB 350. Also, because the power is routed in the dummy die 55, the heat which is generated from the internal resistance of the dummy die 55 is not transferred to the die cube 50, but rather has a heat dissipation path through the device die 30 and/or supporting substrate 65.

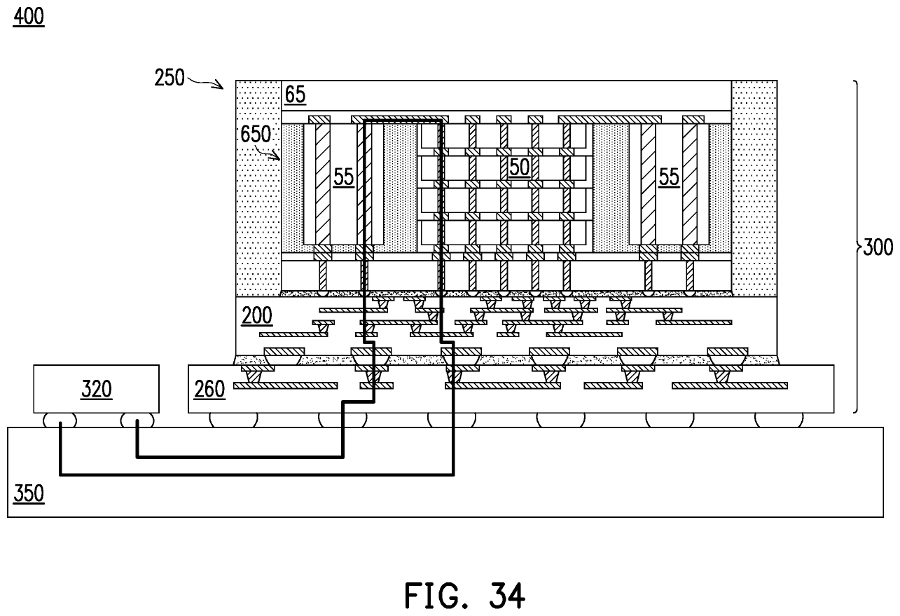

In FIG. 34, a structure 400 is formed, in accordance with other embodiments. The structure 400 utilizes a 3DIC package 650, which is similar to the 3DIC package 600, except that the illustrated cross-section of the 3DIC package 650 includes what appears to be a dummy die 55 on each side of the die cube 50. An example power routing is shown through the CoWoS device 300. As illustrated in FIG. 34, the power routing has a power plane through the dummy die 55 and through the TSVs 52, sequentially.

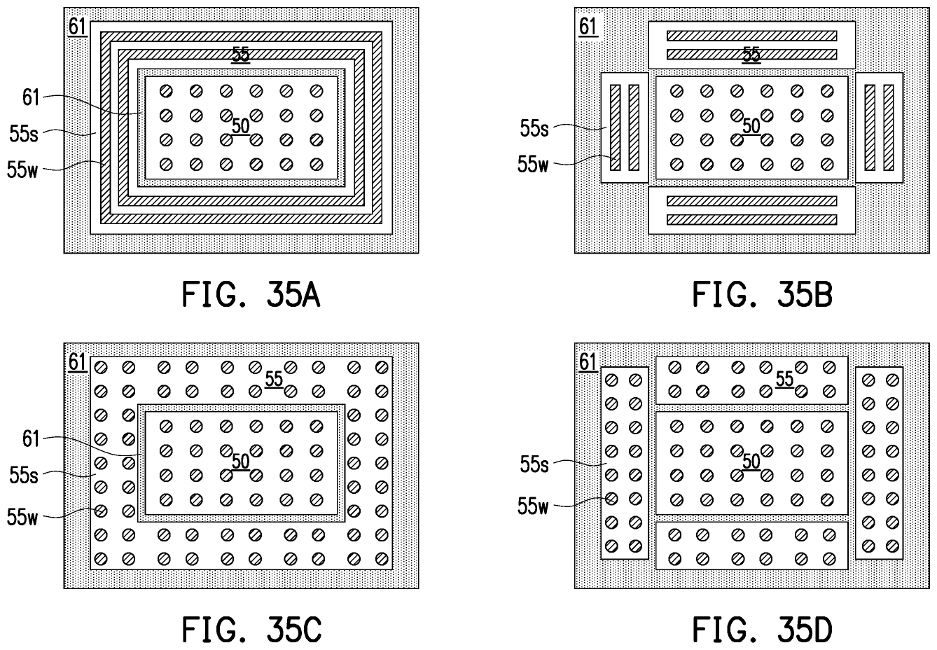

FIGS. 35A, 35B, 35C, and 35D illustrate top down views which include different possible configurations for the dummy die 55 of FIG. 34. The 3DIC package 650 is provided for reference. As illustrated in FIGS. 35A and 35C, the substrate 55s of the dummy die 55 has a ring configuration, extending completely around the periphery of the 3DIC package 650. In contrast, as illustrated in FIGS. 35B and 35D, the substrate 55s of the dummy die 55 is made up of distinct structures. Four are illustrated for each of FIGS. 35B and 35D, however, more or fewer dummy die 55 structures may be used as desired. FIGS. 35A and 35B utilize the TDV wall 55w, such as discussed above with respect to FIG. 26B. The TDV wall 55w is illustrated as extending completely around the 3DIC package 650 in FIG. 35A, however, it should be appreciated that the TDV wall 55w may extend along the sides of the 3DIC package 650, such as illustrated in FIG. 35B. FIGS. 35C and 35D utilize the TDVs 55v, such as discussed above with respect to FIG. 26A.

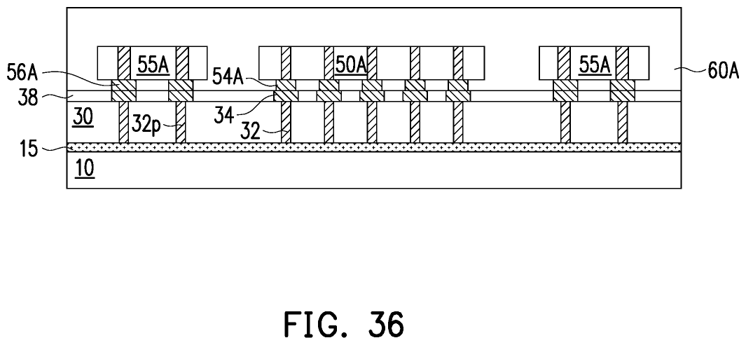

FIGS. 36 through 45 illustrate intermediate views of forming power planes in accordance with other embodiments which utilize dummy dies. It should be understood that these embodiments may be formed using similar processes and materials as those described above, unless otherwise noted. Like references are used to refer to like elements. The embodiments in FIGS. 36 through 45 dispose the device die 30 beneath the device dies 50A, 50B, 50C, 50D, etc. The heat dissipation features are omitted from the illustrated embodiments, however, it should be understood that heat dissipation features may optionally be utilized.

In FIG. 36, a device die 30 is bonded to a carrier substrate 10 using the release layer 15. The device die 30 has TSVs 32 that traverse through the thickness of the device die 30. In some embodiments, the TSVs 32 may only traverse partially through the substrate of the device die 30 and may be revealed by a subsequent process. The TSV 32p is separately labeled as corresponding to the TSVs 32 which are utilized by the dummy die to provide a power plane to the device dies. Insulating layer 38 is formed over the device die 30 and bond pads 34 are formed with in the insulating layer 38.

A device die 50A is bonded to the device die 30 using an acceptable bonding process, such as described above with respect to FIG. 10. Similarly, a dummy die 55A is bonded to the device die 30 by the bond pads 56A. The bonding process may be as described above with respect to FIG. 10. The dummy die 55A may be taller or shorter than the device die 50A. An encapsulant 60A is deposited over and laterally surrounding the device die 50A and the dummy die 55A. In some embodiments, the encapsulant 60A may also extend below the device die 50A and the dummy die 55A and laterally surround the contact pads 54. In other embodiments, a separate underfill may be used. In yet other embodiments, the face of the device die 50A and the dummy die 55A may contact the face of the insulating layer 38 directly, such that there is no space between the bottom surface of the device die 50A and the insulating layer 38 and between the bottom surface of the dummy die 55A and the insulating layer 38.

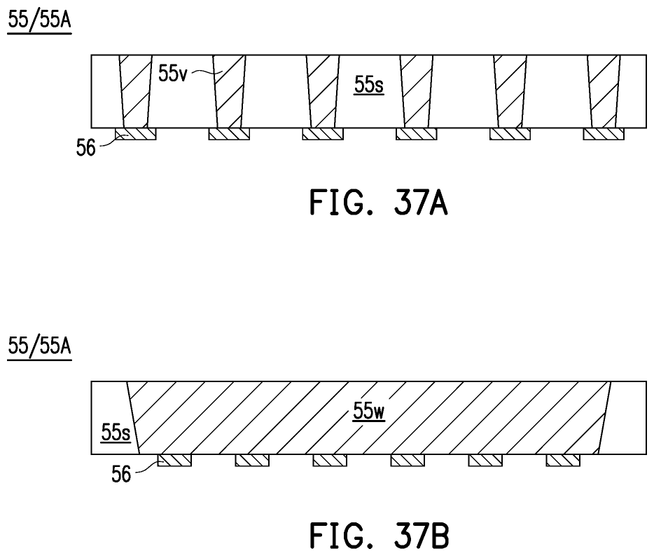

FIGS. 37A and 37B illustrate perpendicular cross section of two different configurations for the dummy dies 55, such as dummy die 55A. The dummy dies 55 of FIGS. 37A and 37B are similar to those discussed above with respect to FIGS. 26A and 26B, respectively, except that the thickness of the dummy dies 55 of FIGS. 37A and 37B are thinner, being closer in thickness to the thickness of one particular device die, such as device die 50A, whereas the thickness of the dummy dies 55 of FIGS. 26A and 26B are closer in thickness to the thickness of the die cube 50. In other words, the thickness of the dummy dies 55 of FIGS. 26A and 26B may be between 2 and 8 times thicker or more than the thickness of the dummy dies 55 of FIGS. 37A and 37B. Each of the dummy dies 55, such as dummy die 55A, may have top down views similar to the illustrated views of the dummy dies 55 of FIGS. 35A, 35B, 35C, and 35D.

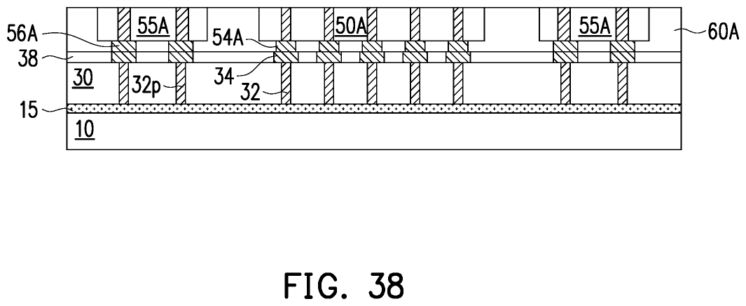

In FIG. 38, a planarization process, such as a CMP process may be used to level the upper surfaces of the encapsulant 60A, the dummy die 55A, and the device die 50A. In some embodiments, the TSVs 52 of the device die 50A and/or the TDVs 55v or TDV wall may be buried in their respective substrates. In such embodiments, the planarization process may expose the TSVs 52 and/or TDVs 55v or TDV walls 55w. In some embodiments, conductive features may be formed over the TSVs 52 and/or TDVs 55v or TDV walls 55w for bonding a next tier of device dies 50 (e.g., device die 50B) and dummy dies 55 (e.g., dummy die 55B). The conductive features may be formed using processes and materials similar to those used to form the conductive features 34B (and insulating layer 38B) discussed above with respect to FIG. 8.

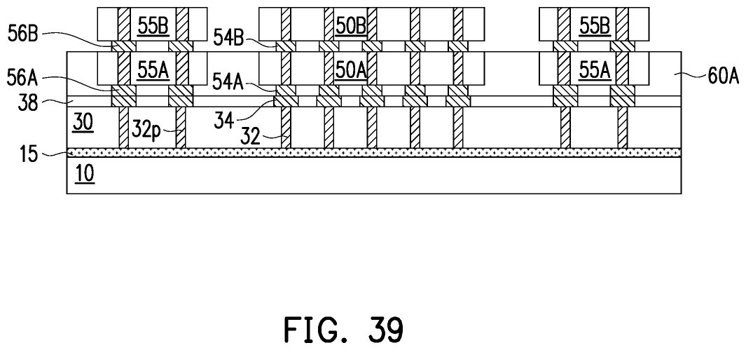

In FIG. 39, a second tier of device dies 50 (i.e., device die 50B) and dummy dies 55 (i.e., dummy die 55B) may be bonded to the respective back sides of the previous tier. The bonding processes may be as described above with respect to FIG. 10, and may include, for example, the formation of conductive features 34B in an insulating layer 38B prior to the bonding of the device die 50B.

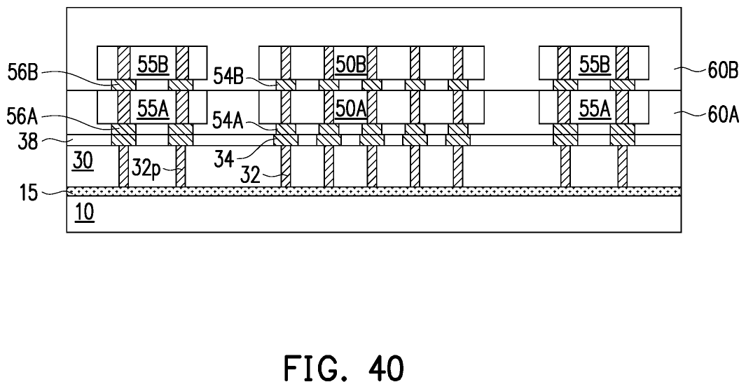

In FIG. 40, an encapsulant 60B is deposited over and laterally surrounding the device die 50B and the dummy die 55B. In some embodiments, the encapsulant 60B may also extend below the device die 50B and the dummy die 55B and laterally surround the bond pads 54B. In other embodiments, a separate underfill may be used. In yet other embodiments, the face of the device die 50B and the dummy die 55B may contact the backsides of the device die 50A and the dummy die 55A directly, such that there is no space between the bottom surface of the device die 50B and the device die 50A and between the bottom surface of the dummy die 55B and the dummy die 55A.

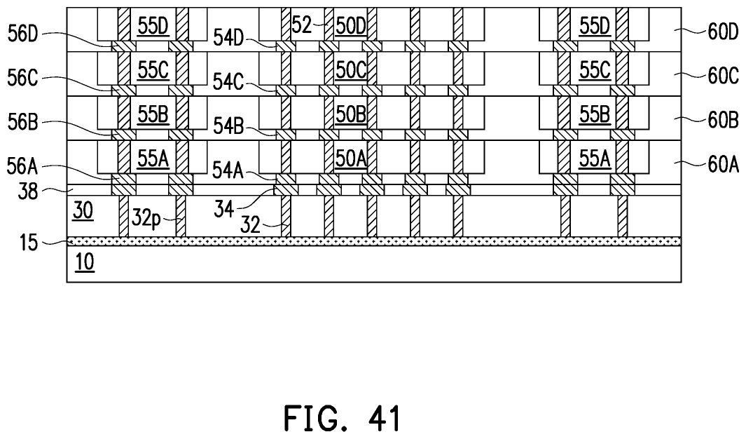

In FIG. 41, the encapsulant 60B is planarized by a planarization process, such as a CMP process and the process of bonding device dies 50, such as device dies 50C and 50D, and dummy dies 55, such as dummy dies 55C and 55D is repeated until a desired number of device dies 50 and corresponding dummy dies 55 are attached. After each tier of device dies 50 and dummy dies 55 are attached, an encapsulant, such as the encapsulant 60C and 60D, may be deposited.

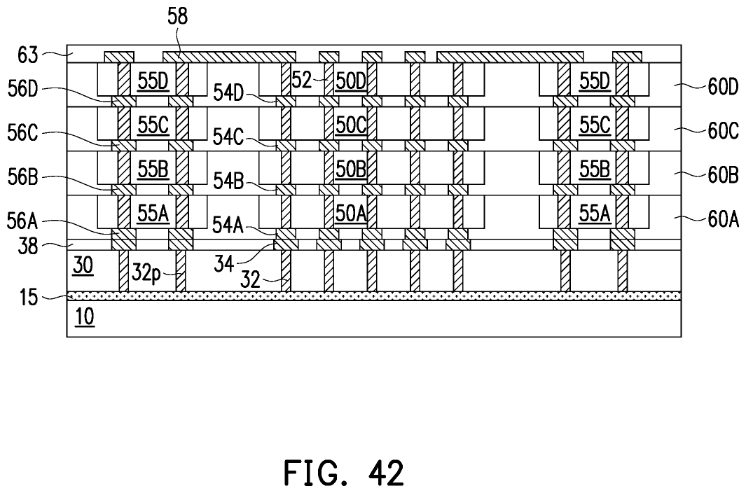

In FIG. 42, metal lines 58 may be formed in an insulating layer 63. In some embodiments, the metal lines 58 are formed first, for example, using a photoresist as a deposition template, and then the insulating layer 63 formed thereover, using for example a spin-on process or other suitable process. In other embodiments, the insulating layer 63 may be formed first and the metal lines formed using, for example, a damascene process. The metal lines 58 couple the TDVs 55v or TDV walls 55w in the dummy die 55 to the device dies 50, thereby providing a power plane.

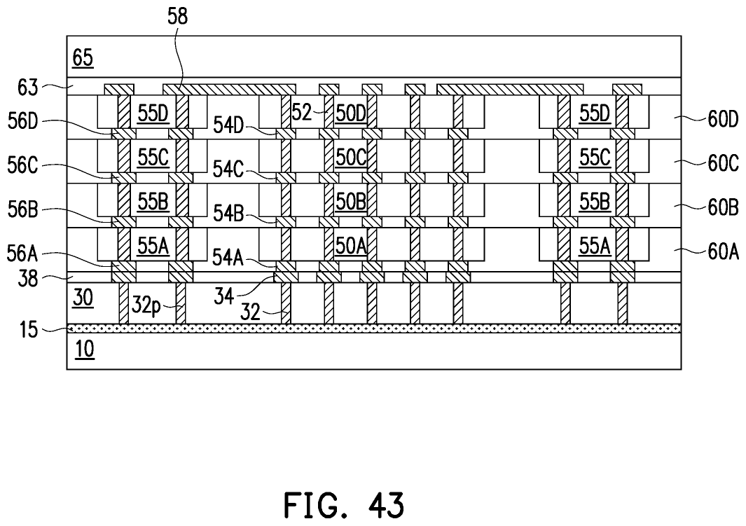

In FIG. 43, a supporting substrate 65 may be bonded to the upper surfaces of the insulating layer 63. The supporting substrate 65 may be similar to the supporting substrate 65 of FIG. 29 and attached in the same manner thereof.

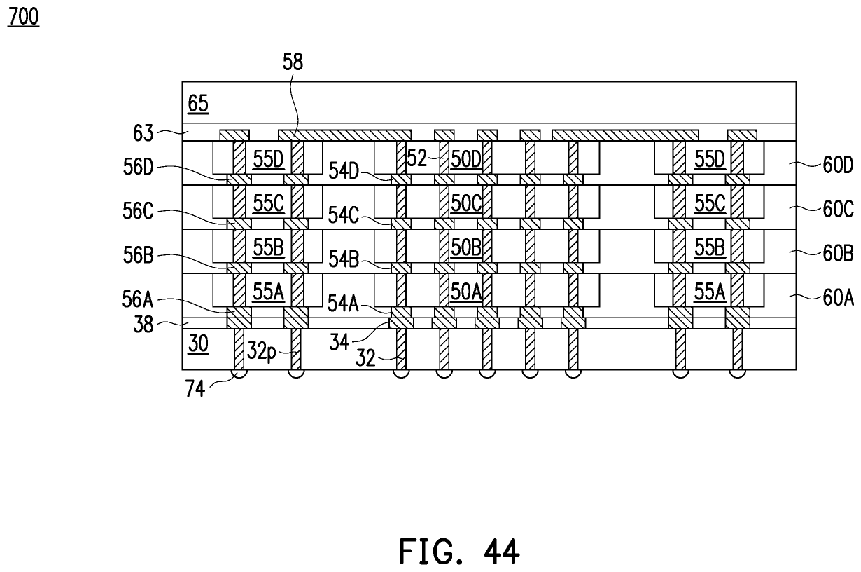

In FIG. 44 the carrier substrate 10 may be debonded. Next, the connectors 74 attached to the front side of the device die 30. The resulting package is the 3DIC package 700. It should be understood that in some embodiments, multiples of the 3DIC package 700 may be formed at the same time on a larger substrate and then singulated, to release individual 3DIC packages 700, similar to that described above with respect to FIG. 14.

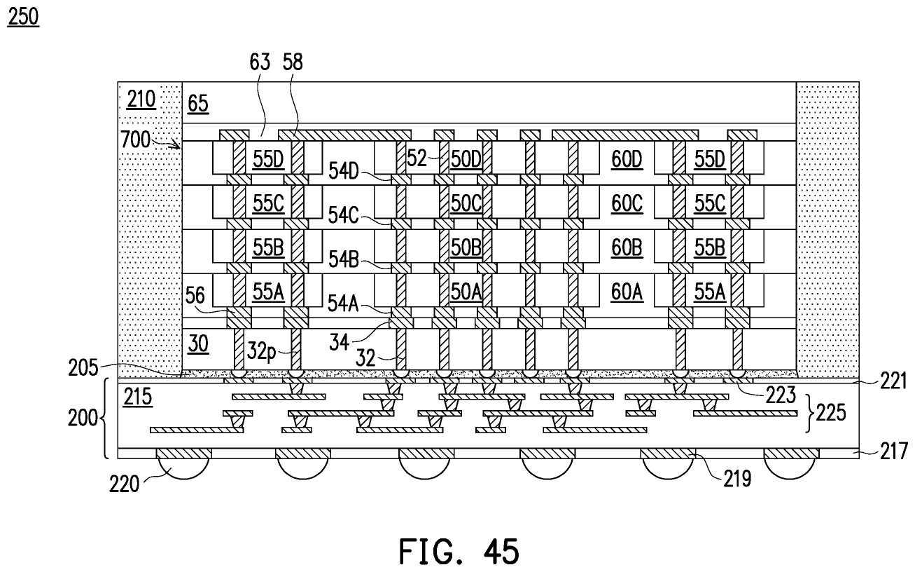

In FIG. 45, the 3DIC package 700 is mounted to the interposer 200. The connectors 74 of the package 700 may be attached to corresponding contact pads 223 on the interposer 200. An underfill material 205 may be deposited under the package 100 and around the connectors 74. After the underfill material 205 is formed, a molding material 210 is formed around the 3DIC package 700, such that the package 700 is embedded in the molding material 210. The structure illustrated in FIG. 45 may be referred to as a Chip-On-Wafer (CoW) structure, and the device formed is referred to as the CoW device 250.

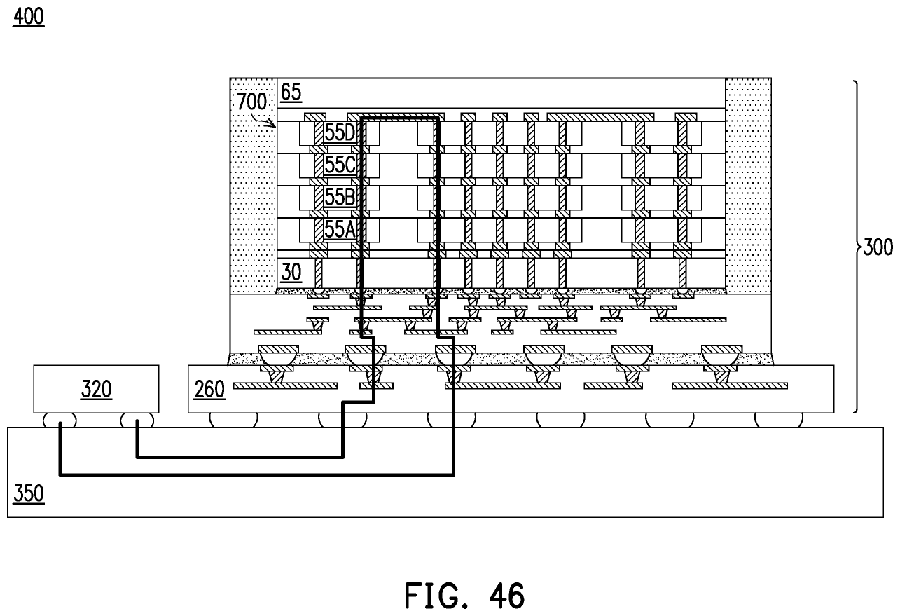

As referenced in FIG. 46, a structure 400 is formed, in accordance with some embodiments. The CoW device 250 may be attached to a substrate in a similar manner as described above with respect to FIG. 16 to form a CoWoS device 300. The CoWoS device 300 may then be attached to PCB 350. The power chip 320 may provide regulated power to the CoWoS device 300. An example power routing is shown through the CoWoS device 300. As illustrated in FIG. 46, the power routing has a power plane through the dummy dies 55A, 55B, 55C, and 55D, and through the TSVs 52, sequentially. Because the CoW device 250 utilizes the dummy dies 55A, 55B, 55C, and 55D for power management, the internal resistance of the CoW device 250 is reduced, causing less waste heat generation from excessive resistance. The dummy dies 55A, 55B, 55C, and 55D also provide good heat transfer through the CoW device 250, which may radiate to heat dissipating features and/or through the substrate 260 and PCB 350. Also, because the power is routed in the dummy dies 55A, 55B, 55C, and 55D, the heat which is generated from the internal resistance of the dummy dies 55A, 55B, 55C, and 55D is not transferred to the device dies 50A, 50B, 50C, and 50D, but rather has a heat dissipation path through the device die 30 and/or supporting substrate 65.

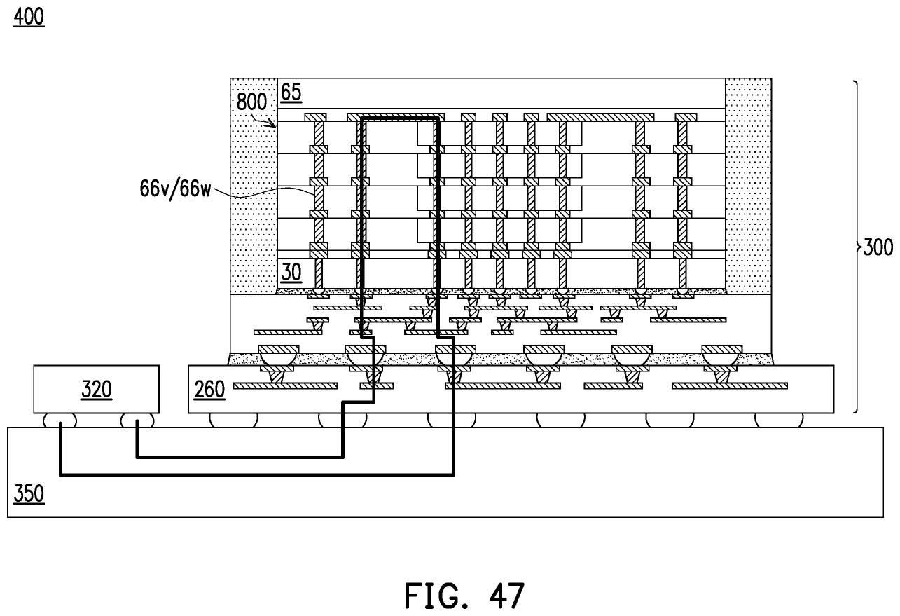

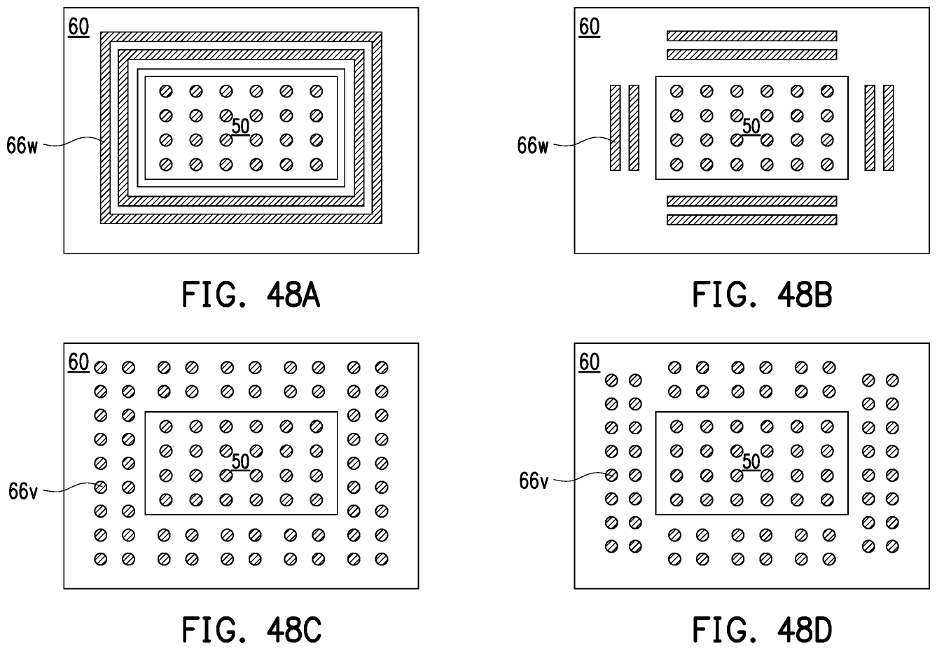

In FIG. 47, a structure 400 is formed, in accordance with some embodiments. In FIG. 47, the CoW device 250 includes the 3DIS 800. The power plane in the 3DIC 800 may be formed using processes and materials similar to those used to form the TDV walls 66A, 66B, 66C, 66D; the conductive features 34B, 34C, 34D; the insulating layers 38B, 38C, and 38D; and the encapsulants 60A, 60B, 60C, and 60D. In FIG. 47, however, the device die 30 is disposed on the bottom and a supporting substrate 65 is disposed on the top. An example power routing is shown through the CoWoS device 300 of FIG. 47. FIGS. 48A, 48B, 48C, and 48D illustrate horizontal cross-sections of the 3DIC structures 800. As noted therein, the TDV walls 66w of FIGS. 48A and 48B may be formed to either surround the device dies 50 or be formed along sides of the device dies 50. The TDVs 66v of FIGS. 48C and 48D may be formed to surround the device dies 50 or to be formed along sides of the device dies 50.

Still referring to FIG. 47, the CoW device 250 may be attached to a substrate in a similar manner as described above with respect to FIG. 16 to form a CoWoS device 300. The CoWoS device 300 may then be attached to PCB 350. The power chip 320 may provide regulated power to the CoWoS device 300. An example power routing is shown through the CoWoS device 300. As illustrated in FIG. 47, the power routing has a power plane through the TDVs 66v or TDV walls 66w, and through the TSVs 52, sequentially. Because the CoW device 250 utilizes the TDVs 66v or TDV walls 66w for power management, the internal resistance of the CoW device 250 is reduced, causing less waste heat generation from excessive resistance. The TDVs 66v or TDV walls 66w also provide good heat transfer through the CoW device 250, which may radiate to heat dissipating features and/or through the substrate 260 and PCB 350. Also, because the power is routed in the dummy dies TDVs 66v or TDV walls 66w, the heat which is generated from the internal resistance of the power plane through TDVs 66v or TDV walls 66w is not transferred to the device dies 50A, 50B, 50C, and 50D, but rather has a heat dissipation path through the device die 30 and/or supporting substrate 65.

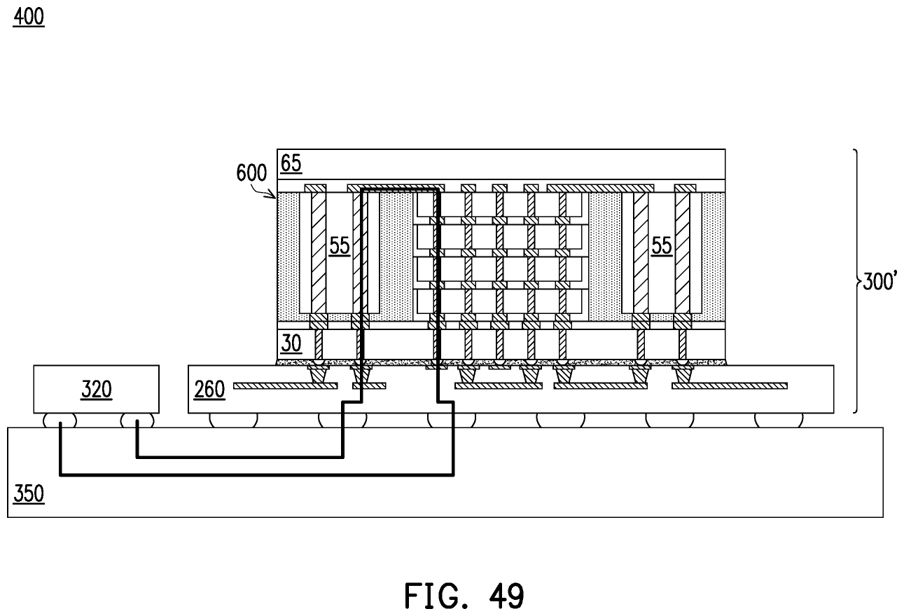

In FIG. 49, a structure 400 is illustrated, in accordance with some embodiments. In FIG. 49, the 3DIC package 600 is bonded directly to the substrate 260. In such embodiments, the interposer 200 is omitted.

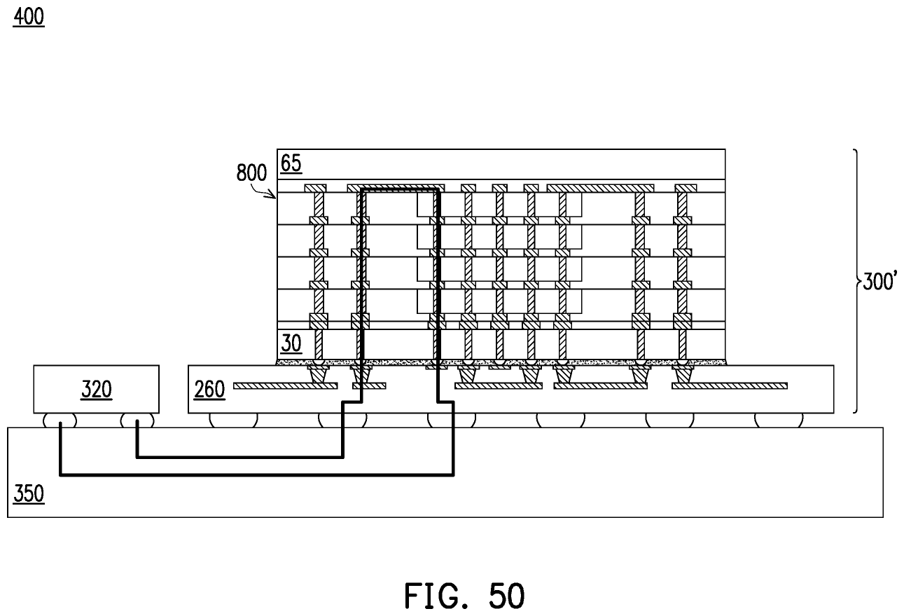

Similarly, in FIG. 50, a structure 400 is illustrated, in accordance with other embodiments. In FIG. 50, the 3DIC structure 800 is bonded directly to the substrate 260. In such embodiments, the interposer 200 is omitted.

Embodiments achieve several advantages. Because a power plane may be run through a conductive structure, e.g., the lid, TDV wall, TDV via, or dummy structures, the power supplied to a 3DIC can have less resistance, resulting in less power consumption and heat generation. Although, the illustrated embodiments generally show as an example, one power plane, embodiments also provide for multiple power planes, for example, one held at one reference voltage and another power plane, for example held at another reference voltage.

One embodiment is a method including mounting a second device die to a first device die to form a first package. The method also includes mounting the first package to a substrate. The method also includes coupling a power source line to the first package. The method also includes electrically coupling the power source line to a power plane of the first package, using a heat dissipation lid as the power plane or conductive features embedded in an encapsulant material adjacent the second die as the power plane. In an embodiment, the method further includes attaching a dummy structure to the first device die, the dummy structure including the power plane. In an embodiment, the dummy structure includes a ringed substrate that surrounds the second device die. In an embodiment, the power plane in the dummy structure includes a via wall extending from a top of the dummy structure to a bottom of the dummy structure and along a length of the dummy structure. In an embodiment, the method further includes flipping the first package and mounting the first package to the substrate by the second device die; and disposing a heat dissipating feature over the first package, the heat dissipating feature adjacent the first device die. In an embodiment, the method further includes depositing a conductive material over the first package; and attaching a split lid to the first package by the conductive material. In an embodiment, after mounting a second device die to the first device die, the method includes depositing an encapsulant laterally surrounding the first die; forming an opening in the encapsulant; and depositing a through-die via (TDV) wall in the opening, the TDV wall extending lengthwise along an edge of the second device die. In an embodiment, the method further includes encapsulating the second device die by an encapsulant; and forming a conductive line on an upper surface of an encapsulant between the power plane and a through-silicon via disposed in the second device, the power plane disposed in the encapsulant.

Another embodiment is a method including bonding one or more second device dies to a first device die, the one or more second device dies arranged in a vertical stack. The method also includes forming a vertical power plane adjacent the one or more second device dies. The method also includes electrically coupling the first device die to the vertical power plane at one end of the vertical power plane. The method also includes electrically coupling a through via of the one or more second devices to the vertical power plane at an opposite end of the vertical power plane. In an embodiment, the vertical power plane includes a heat dissipating lid. In an embodiment, the heat dissipating lid is in at least two pieces, the method further including, bonding an underside of the heat dissipating lid to the first device die by a conductive material. In an embodiment, forming the vertical power plane includes: after bonding the one or more second device dies, depositing an encapsulant to surrounding the one or more second device dies; forming an opening in the encapsulant, the opening exposing a conductive element beneath the one or more second device dies; and depositing a metal plug in the opening, the vertical power plane including the metal plug. In an embodiment, the vertical power plane includes a dummy die, the dummy die including a conductive element embedded within a substrate. In an embodiment, the conductive element of the dummy die includes an array of through vias disposed throughout the substrate. In an embodiment, the vertical power plane extends horizontally along a length of an edge of one device die of the one or more second device dies.

Another embodiment is a semiconductor device. The semiconductor device includes at least one device die disposed on a substrate, where the at least one device die has a through-silicon via (TSV) structure therein. The semiconductor device also includes a voltage regulator disposed on the substrate and laterally separated from the at least one device die. The semiconductor device also includes a metal structure disposed between the at least one device die and the voltage regulator, where the voltage regulator receives a power delivery passing through the TSV structure and the metal structure sequentially. In an embodiment, the metal structure corresponds to a heat dissipation lid disposed over the at least one device die. In an embodiment, the metal structure corresponds to one or more dummy dies disposed adjacent to the at least one device die, the dummy die including a conductive element traversing through the substrate. In an embodiment, the at least one device is disposed in a corresponding number of encapsulant layers, where the metal structure corresponds to a conductive structure disposed in the encapsulant layers, apart from the at least one device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
mounting a second device die to a first device die to form a first package;
mounting the first package to a substrate;
coupling a power source line to the first package; and
electrically coupling the power source line to a power plane of the first package, using a heat dissipation lid as the power plane or conductive features embedded in an encapsulant material adjacent the second die as the power plane.

2. The method of claim 1, further comprising:
attaching a dummy structure to the first device die, the dummy structure including the power plane.

3. The method of claim 2, wherein the dummy structure includes a ringed substrate that surrounds the second device die.

4. The method of claim 3, wherein the power plane in the dummy structure comprises a via wall extending from a top of the dummy structure to a bottom of the dummy structure and along a length of the dummy structure.

5. The method of claim 1, further comprising:
flipping the first package and mounting the first package to the substrate by the second device die; and
disposing a heat dissipating feature over the first package, the heat dissipating feature adjacent the first device die.

6. The method of claim 5, further comprising:
depositing a conductive material over the first package; and
attaching a split lid to the first package by the conductive material.

7. The method of claim 1, wherein after mounting a second device die to the first device die, depositing an encapsulant laterally surrounding the first die;
forming an opening in the encapsulant; and
depositing a through-die via (TDV) wall in the opening, the TDV wall extending lengthwise along an edge of the second device die.

8. The method of claim 1, further comprising:
encapsulating the second device die by an encapsulant; and
forming a conductive line on an upper surface of an encapsulant between the power plane and a through-silicon via disposed in the second device, the power plane disposed in the encapsulant.

9. A method comprising:
bonding one or more second device dies to a first device die, the one or more second device dies arranged in a vertical stack;
forming a vertical power plane adjacent the one or more second device dies;
electrically coupling the first device die to the vertical power plane at one end of the vertical power plane; and
electrically coupling a through via of the one or more second devices to the vertical power plane at an opposite end of the vertical power plane.

10. The method of claim 9, wherein the vertical power plane comprises a heat dissipating lid.

11. The method of claim 10, wherein the heat dissipating lid is in at least two pieces, further comprising, bonding an underside of the heat dissipating lid to the first device die by a conductive material.

12. The method of claim 9, wherein forming the vertical power plane comprises:
after bonding the one or more second device dies, depositing an encapsulant to surrounding the one or more second device dies;
forming an opening in the encapsulant, the opening exposing a conductive element beneath the one or more second device dies; and
depositing a metal plug in the opening, the vertical power plane comprising the metal plug.

13. The method of claim 9, wherein the vertical power plane includes a dummy die, the dummy die comprising a conductive element embedded within a substrate.

14. The method of claim 13, wherein the conductive element of the dummy die includes an array of through vias disposed throughout the substrate.

15. The method of claim 9, wherein the vertical power plane extends horizontally along a length of an edge of one device die of the one or more second device dies.

16. A semiconductor device, comprising:
a substrate;
at least one device die disposed on the substrate, wherein the at least one device die has a through-silicon via (TSV) structure therein;
a voltage regulator disposed on the substrate and laterally separated from the at least one device die; and
a metal structure disposed between the at least one device die and the voltage regulator, wherein the voltage regulator receives a power delivery passing through the TSV structure and the metal structure sequentially.

17. The device of claim 16, wherein the metal structure corresponds to a heat dissipation lid disposed over the at least one device die.

18. The device of claim 16, wherein the metal structure corresponds to one or more dummy dies disposed adjacent to the at least one device die, the dummy die including a conductive element traversing through the substrate.

19. The device of claim 16, wherein the at least one device is disposed in a corresponding number of encapsulant layers, wherein the metal structure corresponds to a conductive structure disposed in the encapsulant layers, apart from the at least one device.

20. The device of claim 16, wherein the metal structure corresponds to a via wall, the via wall extending from an upper surface of the at least one device die to a lower surface of the at least one device die, the via wall extending along a length of the at least one device die.
